(19) United States
(12) Patent Application Publication
(10) Pub. No.: US 2026/0271581 A1
(43) Pub. Date: Sep. 10, 2026

(54) DISPLAY DEVICE, METHOD OF MANUFACTURING THE SAME, AND ELECTRONIC DEVICE INCLUDING THE DISPLAY DEVICE

(71) Applicant: Samsung Display Co., LTD., Yongin-si (KR)

(72) Inventors: Gi Hyun LEE, Yongin-si (KR); Seung In CHOI, Yongin-si (KR)

(21) Appl. No.: 19/351,638

(22) Filed: Oct. 7, 2025

(30) Foreign Application Priority Data
Mar. 4, 2025 (KR) 10-2025-0027585
May 16, 2025 (KR) 10-2025-0063714

(51) Int. Cl. H10K 59/80; H10K 59/12; H10K 59/122

(52) U.S. Cl. CPC H10K 59/80515; H10K 59/1201; H10K 59/122

(57) ABSTRACT

A display device includes a substrate including first and second areas, an anode conductive layer disposed on the substrate and including an auxiliary electrode, a pixel defining layer covering an end of the auxiliary electrode to expose at least a portion of an upper surface of the auxiliary electrode, a light-emitting layer disposed on the anode conductive layer to expose at least a portion of the upper surface of the auxiliary electrode, and a common electrode disposed on the light-emitting layer to contact the auxiliary electrode. The first area includes an area exposed by the pixel defining layer on the upper surface of the auxiliary electrode, the second area includes an area exposed by the light-emitting layer on the upper surface of the auxiliary electrode, and an area where the first and second areas overlap in a thickness direction of the substrate may be smaller than the second area.

This application claims priority to Korean Patent Application No. 10-2025-0027585, filed on Mar. 4, 2025 and Korean Patent Application No. 10-2025-0063714, filed on May 16, 2025, and all the benefits accruing therefrom under 35 U.S.C. § 119, the contents of which in their entirety are herein incorporated by reference.

### BACKGROUND

### 1. Field

The specification relates to a display device, a method of manufacturing the display device, and an electronic device including the display device.

### 2. Description of the Related Art

Electroluminescence displays may be divided into inorganic light-emitting displays and organic light-emitting displays depending on the material of a light-emitting layer. An active matrix type organic light-emitting display includes an organic light-emitting diode (“OLED”) that emits light by itself and has advantages of fast response speed, high luminous efficiency, high luminance and wide viewing angle. In the organic light-emitting display, the OLED is formed in each pixel. The organic light-emitting display not only has fast response speed and excellent luminous efficiency, luminance and viewing angle, but also has excellent contrast ratio and color gamut because it may express a black gray level as complete black.

### SUMMARY

A feature of the specification is to provide a display device with improved power consumption.

However, features of the disclosure are not restricted to the one set forth herein. The above and other features of the disclosure will become more apparent to one of ordinary skill in the art to which the disclosure pertains by referencing the detailed description of the disclosure given below.

In an embodiment of the disclosure, a display device includes a substrate including a first area and a second area, an anode conductive layer disposed on the substrate and including an auxiliary electrode, a pixel defining layer disposed to cover an end of the auxiliary electrode to expose at least a portion of an upper surface of the auxiliary electrode, a light-emitting layer disposed on the anode conductive layer to expose at least a portion of the upper surface of the auxiliary electrode, and a common electrode disposed on the light-emitting layer to contact the auxiliary electrode. The first area includes an area exposed by the pixel defining layer on the upper surface of the auxiliary electrode, the second area includes an area exposed by the light-emitting layer on the upper surface of the auxiliary electrode, and an area where the first area and the second area overlap in a thickness direction of the substrate may be smaller than the second area.

In an embodiment, the anode conductive layer further includes a pixel electrode, and at least a portion of the light-emitting layer may be disposed between the pixel electrode and the common electrode.

In an embodiment, the substrate may further include a display area including the first area and the second area, and a non-display area surrounding the display area.

In an embodiment, a first boundary is defined based on a boundary of the first area, a second boundary is defined based on a boundary of the second area, and the first boundary may include a plurality of points overlapping the second boundary in the thickness direction.

In an embodiment, a first boundary is defined based on a boundary of the first area, a second boundary is defined based on a boundary of the second area, and the first boundary may include a first point and a second point overlapping the second boundary in the thickness direction.

In an embodiment, a first center is defined from a center of the first area, a second center is defined from a center of the second area, and an imaginary straight line connecting the first point and the second point may be defined.

In an embodiment, the second center, the imaginary straight line, and the first center may be sequentially arranged.

In an embodiment, the second center may overlap the imaginary straight line in the thickness direction.

In an embodiment, the imaginary straight line, the second center, and the first center may be sequentially arranged.

In an embodiment, the auxiliary electrode may contact the common electrode in the area where the first area and the second area overlap in the thickness direction of the substrate.

In an embodiment of the disclosure, a method of manufacturing a display device includes forming a substrate which includes a first area and a second area, forming an anode conductive layer which is disposed on the substrate and includes an auxiliary electrode, forming a pixel defining layer which is disposed to cover an end of the auxiliary electrode to expose at least a portion of an upper surface of the auxiliary electrode, forming a light-emitting layer which is disposed on the anode conductive layer, removing at least a portion of the light-emitting layer to expose at least a portion of the upper surface of the auxiliary electrode, and detecting a position of the first area and a position of the second area. The first area includes an area exposed by the pixel defining layer on the upper surface of the auxiliary electrode, the second area includes an area exposed by the light-emitting layer on the upper surface of the auxiliary electrode, and an area where the first area and the second area overlap in a thickness direction of the substrate may be smaller than the second area.

In an embodiment, the detecting the position of the first area and the position of the second area may be performed using a deep learning detection method for detecting a type and position of an object (object detection).

In an embodiment, the method may further include comparing positions of the first area and the second area.

In an embodiment, the comparing the positions of the first area and the second area may include: defining a first boundary based on a boundary of the first area, defining a second boundary based on a boundary of the second area, defining an imaginary straight line by connecting a plurality of points where the first boundary and the second boundary overlap in the thickness direction, defining a first center from a center of the first area, and defining a second center from a center of the second area.

In an embodiment, the comparing the positions of the first area and the second area may further include comparing positions of the imaginary straight line, the second center, and the first center.

In an embodiment of the disclosure, an electronic device includes a processor providing an image signal, a display module receiving the image signal from the processor and displaying an image, and a power module supplying power to the display module. The display module includes a substrate including a first area and a second area, an anode conductive layer disposed on the substrate and including an auxiliary electrode, a pixel defining layer disposed to cover an end of the auxiliary electrode to expose at least a portion of an upper surface of the auxiliary electrode, a light-emitting layer disposed on the anode conductive layer to expose at least a portion of the upper surface of the auxiliary electrode, and a common electrode disposed on the light-emitting layer to contact the auxiliary electrode. The first area includes an area exposed by the pixel defining layer on the upper surface of the auxiliary electrode, the second area includes an area exposed by the light-emitting layer on the upper surface of the auxiliary electrode, and an area where the first area and the second area overlap in a thickness direction of the substrate may be smaller than the second area.

In an embodiment, the auxiliary electrode may contact the common electrode in the area where the first area and the second area overlap in the thickness direction of the substrate.

In an embodiment, a first boundary is defined based on a boundary of the first area, a second boundary is defined based on a boundary of the second area, and the first boundary may include a first point and a second point overlapping the second boundary in the thickness direction.

In an embodiment, a first center is defined from a center of the first area, a second center is defined from a center of the second area, and an imaginary straight line connecting the first point and the second point may be defined.

In an embodiment, the imaginary straight line, the second center, and the first center may be sequentially arranged.

A detection unit clearly outputs a first post-signal when the entirety of the second area overlaps a first area. When the entirety of the second area does not overlap (is misaligned with) the first area, the detection unit clearly outputs a second post-signal. However, when an overlapping area (e.g., a second contact area) between the second area and the first area is smaller than the second area, the detection unit may output a third post-signal. The output of the third post-signal may be a case where the detection unit cannot clearly determine whether an appropriate contact area (e.g., the second contact area) has been secured or has not been secured. The specification provides a detailed determination process for a display device to which the third post-signal is output, thereby enabling a process to be restarted.

In addition, according to the disclosure in the specification, the type of a recognition signal generated for a display device to which the third post-signal is output may be identified. Specifically, it may be identified whether the recognition signal has been generated because it was impossible to determine a positional relationship between the first area and the second area or whether the contact area has been appropriately secured despite the generation of the recognition signal.

The specification may identify a display device in which the contact area has been appropriately secured. Therefore, a display device with reduced voltage drop phenomenon and improved power consumption may be provided.

However, the effects of the disclosure are not restricted to the one set forth herein. The above and other effects of the disclosure will become more apparent to one of daily skill in the art to which the disclosure pertains by referencing the detailed description of the disclosure given below.

### BRIEF DESCRIPTION OF THE DRAWINGS

These and/or other features will become apparent and more readily appreciated from the following description of the embodiments, taken in conjunction with the accompanying drawings in which:

FIG. 1 is a perspective view of a display device in an embodiment of the specification;

FIG. 2 is a cross-sectional view taken along line X1-X1′ of FIG. 1;

FIG. 3 is a cross-sectional view of a display device in an embodiment of the specification;

FIG. 4 is a plan view illustrating a state in which connection films are attached to wiring pads of the display device in the embodiment of the specification;

FIG. 5 is a plan view illustrating a state in which the connection films are not attached to the wiring pads of the display device in the embodiment of the specification;

FIG. 6 illustrates pixels and lines of the display device in the embodiment of the specification;

FIG. 7 is a schematic plan view of a part of a display area of a display substrate;

FIG. 8 is a cross-sectional view taken along line X2-X2′ of FIG. 7;

FIG. 9 is an equivalent circuit diagram of a pixel in an embodiment of the specification;

FIG. 10 is a cross-sectional view of an embodiment of a first transistor of a circuit layer according to the specification;

FIG. 11 is a cross-sectional view of an embodiment of a second transistor and a third transistor of the circuit layer;

FIG. 12 is a cross-sectional view illustrating a process of removing a portion of a light-emitting layer through a laser drilling process;

FIG. 13 is a plan view illustrating positions at which laser drilling margin areas are disposed;

FIG. 14 is a block diagram illustrating a system in which a method of manufacturing a display device in an embodiment of the specification is implemented;

FIG. 15 is a plan view of a display device in embodiments of the specification;

FIG. 16 is a cross-sectional view corresponding to FIG. 15;

FIG. 17 is a block diagram illustrating a system in which a method of manufacturing a display device in an embodiment of the specification is implemented;

FIG. 18 is a plan view of a display device in embodiments of the specification;

FIG. 19 is a cross-sectional view corresponding to FIG. 18;

FIG. 20 is a block diagram illustrating a system in which a method of manufacturing a display device in an embodiment of the specification is implemented;

FIG. 21 is a flowchart illustrating a system in which a method of manufacturing a display device in an embodiment of the specification is implemented;

FIG. 22 is a flowchart detailing a determination process in the method of manufacturing the display device in the embodiment of the specification;

FIG. 23 is a block diagram illustrating a system in which a method of manufacturing a display device in an embodiment of the specification is implemented;

FIG. 24 is a plan view of a display device in embodiments of the specification;

FIG. 25 is a cross-sectional view corresponding to FIG. 24;

FIG. 26 is a block diagram illustrating a system in which a method of manufacturing a display device in an embodiment of the specification is implemented;

FIG. 27 is a plan view of a display device in embodiments of the specification;

FIG. 28 is a cross-sectional view corresponding to FIG. 27;

FIG. 29 is a plan view of a display device in embodiments of the specification;

FIG. 30 is a cross-sectional view corresponding to FIG. 29;

FIG. 31 is a block diagram of an electronic device in an embodiment of the specification; and

FIG. 32 is a schematic diagram of electronic devices according to various embodiments of the specification.

### DETAILED DESCRIPTION

The advantages and features of the embodiments disclosed herein, and methods of achieving them, will become apparent upon reference to the embodiments described in detail with accompanying drawings. However, the disclosure is not limited to the embodiments disclosed herein, but will be embodied in many different forms, and these embodiments are provided merely to make the disclosure complete and to fully inform one of ordinary skill in the art to which the disclosure belongs, and the disclosure is defined by the scope of the claims.

References to an element or layer as being “on” another element or layer include both cases in which another layer or element is directly on top of or interposed between other elements. Throughout this specification, like reference numerals refer to like components. The shapes, sizes, proportions, angles, numbers, etc. disclosed in the drawings to illustrate embodiments are exemplary and are not intended to be limiting to those shown herein.

Although first, second, and the like are used to describe various components, the components are not limited by these terms. Thus, a first component referred to herein may also be a second component within the technical idea of the disclosure. “About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

The terms such as “unit” as used herein are intended to mean a hardware component such as a circuitry that performs a predetermined function. The hardware component may include a field-programmable gate array (“FPGA”) or an application-specific integrated circuit (“ASIC”), for example.

Each of the features of the various embodiments disclosed herein may be combined or combinable with each other, in part or in whole, and may be technically interlocked and operated in a variety of ways, and each embodiment may be practiced independently of or in conjunction with one another.

Specific embodiments will be described below with reference to the accompanying drawings. Configurations that function substantially the same between embodiments are given the same drawing designation and repeated description is omitted.

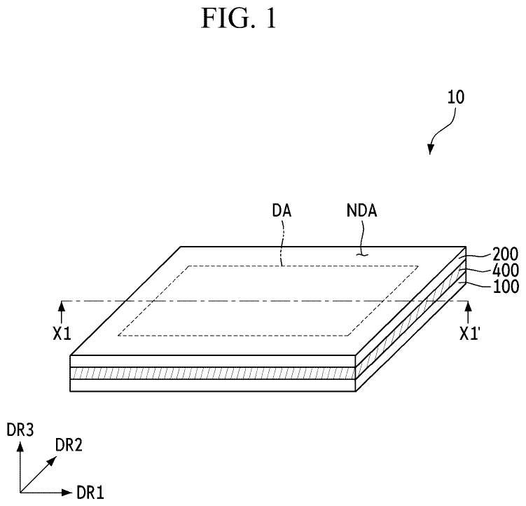

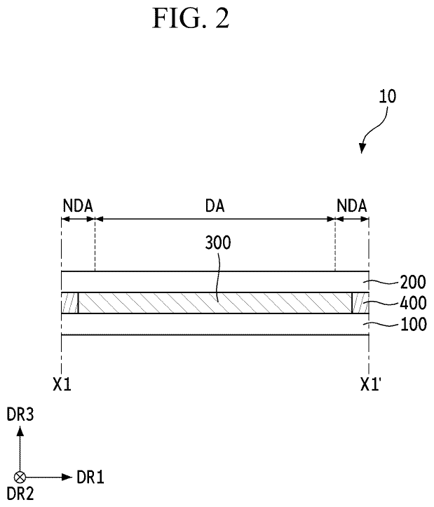

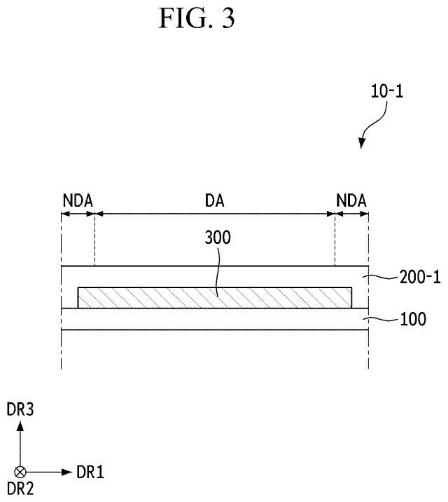

FIG. 1 is a perspective view of a display device 10 in an embodiment of the specification. FIG. 2 is a cross-sectional view taken along line X1-X1′ of FIG. 1. FIG. 3 is a cross-sectional view of a display device 10-1 in an embodiment of the specification.

Referring to FIGS. 1 through 3, the display device 10 may be applied to various electronic devices including small and medium-sized electronic equipment such as tablet personal computers (“PCs”), smartphones, car navigation units, cameras, center information displays (“CIDs”) provided in vehicles, wristwatch type electronic devices, personal digital assistants (“PDAs”), portable multimedia players (“PMPs”) and game consoles and medium and large-sized electronic equipment such as televisions, outdoor billboards, monitors, PCs and notebook computers. These are merely presented as examples, and the display device 10 may also be employed in other electronic devices as long as they are not departing from the spirit of the disclosure.

In an embodiment, the display device 10 may be quadrangular, e.g., rectangular in a plan view. The display device 10 may include two long sides extending in a first direction DR1 and two short sides extending in a second direction DR2 crossing the first direction DR1. Each corner where a long side of the display device 10 meets a short side may be right-angled. However, the disclosure is not limited to this case, and each corner may also form a curved surface. In an embodiment, the long sides may extend in the second direction DR2, and the short sides may extend in the first direction DR1. The planar shape of the display device 10 is not limited to the above example and may also be a circular shape or other shapes.

In the drawings, the first direction DR1 and the second direction DR2 are horizontal directions crossing each other. In an embodiment, the first direction DR1 and the second direction DR2 may be orthogonal to each other, for example. In addition, a third direction DR3 may cross the first direction DR1 and the second direction DR2, e.g., may be a vertical direction orthogonal to the first direction DR1 and the second direction DR2. Unless otherwise defined, in the specification, a direction indicated by an arrow of each of the first through third directions DR1 through DR3 may be also referred to as one side, and the opposite direction may be also referred to as an opposite side. In addition, in the specification, “on”, “upper side”, “above”, “top”, and “upper surface” refer to a direction in which the arrow of the third direction DR3 points in the drawings, and “under”, “lower side”, “below”, “bottom”, and “lower surface” refer to a direction opposite to the direction in which the arrow of the third direction DR3 points in the drawings.

The display device 10 may include a display area DA displaying an image and a non-display area NDA not displaying an image. In an embodiment, the non-display area NDA may be disposed around the display area DA and may surround the display area DA.

In an embodiment, the display device 10 may include a display substrate 100 and a color conversion substrate 200 facing the display substrate 100 and may further include a sealing portion 400 bonding the display substrate 100 and the color conversion substrate 200 together and a filler 300 filling a space between the display substrate 100 and the color conversion substrate 200.

The display substrate 100 may include elements and circuits for displaying an image, e.g., pixel circuits such as switching elements, a pixel defining layer defining emission areas and a non-emission area, which will be described later, in the display area DA, and self-light-emitting elements. In an embodiment, the self-light-emitting elements may include at least one of an organic light-emitting diode, a quantum dot light-emitting diode, an inorganic material-based micro light-emitting diode (e.g., micro light-emitting diode (“LED”)), and an inorganic material-based nano light-emitting diode (e.g., nano LED). For ease of description, a case where the self-light-emitting elements are organic light-emitting diodes will be described below as an example.

The color conversion substrate 200 may be disposed on the display substrate 100 and may face the display substrate 100. In an embodiment, the color conversion substrate 200 may include a color conversion pattern that converts the color of incident light. In an embodiment, the color conversion pattern may include at least any one of a color filter and a wavelength conversion pattern.

The sealing portion 400 may be disposed between the display substrate 100 and the color conversion substrate 200 in the non-display area NDA. The sealing portion 400 may be disposed along edges of the display substrate 100 and the color conversion substrate 200 in the non-display area NDA to surround the display area DA in a plan view. The display substrate 100 and the color conversion substrate 200 may be bonded to each other by the sealing portion 400.

In an embodiment, the sealing portion 400 may include an organic material. In an embodiment, the sealing portion 400 may include, but is not limited to, epoxy resin, for example.

The filler 300 may be disposed in the space surrounded by the sealing portion 400 between the display substrate 100 and the color conversion substrate 200. The filler 300 may fill the space between the display substrate 100 and the color conversion substrate 200.

In an embodiment, the filler 300 may include a material that may transmit light. In an embodiment, the filler 300 may include an organic material. In an embodiment, the filler 300 may include, but is not limited to, a silicon-based organic material or an epoxy-based organic material, for example. In an embodiment, the filler 300 may also be omitted.

In an embodiment, the display device 10-1 may not include the sealing portion 400. In an embodiment, a color conversion substrate 200-1 of the display device 10-1 may be an encapsulation substrate, for example. The color conversion substrate 200-1 may include a protruding portion disposed along the periphery of the color conversion substrate 200-1 and protruding toward a display substrate 100 in the third direction DR3 and a recessed portion surrounded by the protruding portion. The internal space may be sealed by the display substrate 100, the color conversion substrate 200-1, and the protruding portion. A filler 300 may fill the recessed portion.

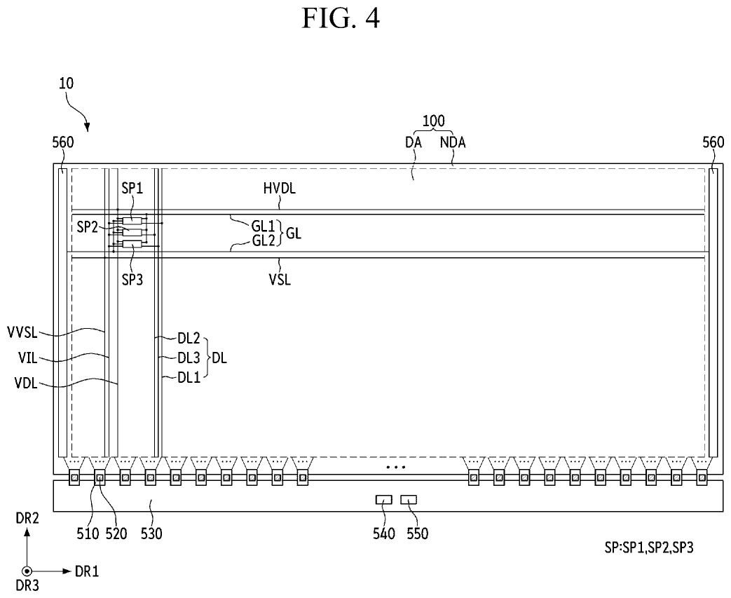

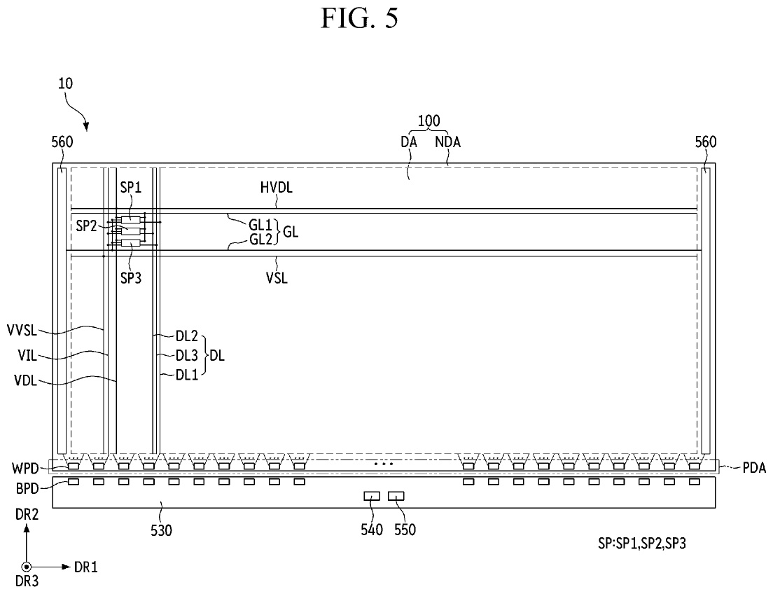

FIG. 4 is a plan view illustrating a state in which connection films 510 are attached to wiring pads WPD of the display device 10 in the embodiment of the specification. FIG. 5 is a plan view illustrating a state in which the connection films 510 are not attached to the wiring pads WPD of the display device 10 in the embodiment of the specification.

Referring to FIGS. 4 and 5, the display device 10 may include the display substrate 100, the connection films 510, display drivers 520, a circuit board 530, a timing controller 540, a power supply unit 550, and a gate driver 560.

The display substrate 100 may be quadrangular, e.g., rectangular in a plan view. In an embodiment, the display substrate 100 may be shaped like a quadrangular, e.g., rectangular plane having long sides in the first direction DR1 and short sides in the second direction DR2, for example. Each corner where a long side extending in the first direction DR1 meets a short side extending in the second direction DR2 may be right-angled or may be rounded to have a selected curvature. The planar shape of the display substrate 100 is not limited to a quadrangular shape, e.g., rectangular shape and may also be other polygonal shapes, a circular shape, or an oval shape. In an embodiment, the display substrate 100 may be formed flat, for example, but the disclosure is not limited to this example. In another embodiment, the display substrate 100 may be bent with a selected curvature.

The display substrate 100 may include the display area DA and the non-display area NDA.

The display area DA may be an area for displaying an image and may be defined as a central area of the display substrate 100. In an embodiment, the display area DA may include pixels SP, gate lines GL, data lines DL, initialization voltage lines VIL, first voltage lines VDL, horizontal voltage lines HVDL, vertical voltage lines VVSL, and second voltage lines VSL.

The pixels SP may be respectively formed in pixel areas intersected by the data lines DL and the gate lines GL. In an embodiment, the pixels SP may include first through third pixels SP1 through SP3. Each of the first through third pixels SP1 through SP3 may be connected to a gate line GL and a data line DL. Each of the first through third pixels SP1 through SP3 may be defined as a smallest unit area that outputs light.

Each of the first through third pixels SP1 through SP3 may include an organic light-emitting diode including an organic light-emitting layer, a quantum dot light-emitting diode including a quantum dot light-emitting layer, a micro light-emitting diode, or an inorganic light-emitting diode including an inorganic semiconductor.

The first pixels SP1 may emit light of a first color or red light, the second pixels SP2 may emit light of a second color or green light, and the third pixels SP3 may emit light of a third color or blue light. Pixel circuits of the first pixels SP1, pixel circuits of the second pixels SP2, and pixel circuits of the third pixels SP3 may be sequentially arranged in a direction opposite to the second direction DR2, but the order of the pixel circuits is not limited to this order.

The gate lines GL may include first gate lines GL1 and second gate lines GL2. The first gate lines GL1 may extend in the first direction DR1 and may be spaced apart from each other in the second direction DR2. The first gate lines GL1 may receive first gate signals from the gate driver 560 and supply the first gate signals to the first through third pixels SP1 through SP3.

The second gate lines GL2 may extend in the first direction DR1 and may be spaced apart from each other in the second direction DR2. The second gate lines GL2 may receive second gate signals from the gate driver 560 and supply the second gate signals to the first through third pixels SP1 through SP3.

The data lines DL may extend in the second direction DR2 and may be spaced apart from each other in the first direction DR1. The data lines DL may include first through third data lines DL1 through DL3. The first through third data lines DL1 through DL3 may supply data voltages to the first through third pixels SP1 through SP3, respectively.

The initialization voltage lines VIL may extend in the second direction DR2 and may be spaced apart from each other in the first direction DR1. The initialization voltage lines VIL may supply initialization voltages received from the display drivers 520 to the respective pixel circuits of the first through third pixels SP1 through SP3. The initialization voltage lines VIL may receive sensing signals from the respective pixel circuits of the first through third pixels SP1 through SP3 and supply the sensing signals to the display drivers 520.

The first voltage lines VDL may extend in the second direction DR2 and may be spaced apart from each other in the first direction DR1. The first voltage lines VDL may supply driving voltages or relatively high potential voltages received from the power supply unit 550 to the first through third pixels SP1 through SP3.

The horizontal voltage lines HVDL may extend in the first direction DR1 and may be spaced apart from each other in the second direction DR2. The horizontal voltage lines HVDL may be connected to the first voltage lines VDL. The horizontal voltage lines HVDL may receive driving voltages or relatively high potential voltages from the first voltage lines VDL.

The vertical voltage lines VVSL may extend in the second direction DR2 and may be spaced apart from each other in the first direction DR1. The vertical voltage lines VVSL may be connected to the second voltage lines VSL. The vertical voltage lines VVSL may supply relatively low potential voltages received from the power supply unit 550 to the second voltage lines VSL.

The second voltage lines VSL may extend in the first direction DR1 and may be spaced apart from each other in the second direction DR2. The second voltage lines VSL may supply relatively low potential voltages to the first through third pixels SP1 through SP3.

The connection relationship between the pixels SP, the gate lines GL, the data lines DL, the initialization voltage lines VIL, the first voltage lines VDL, the horizontal voltage lines HVDL, the vertical voltage lines VVSL, and the second voltage lines VSL may be variously designed and changed according to the number and arrangement of the pixels SP.

The non-display area NDA may be defined as an area other than the display area DA in the display substrate 100. In an embodiment, the non-display area NDA may include fan-out lines connecting the data lines DL, the initialization voltage lines VIL, the first voltage lines VDL and the vertical voltage lines VVSL to the display drivers 520 and may include the gate driver 560 and the wiring pads WPD connected to the connection films 510, for example.

The non-display area NDA may include a pad area PDA where the wiring pads WPD are disposed. The pad area PDA may be disposed next (adjacent) to a side of the display device 10. In an embodiment, the pad area PDA may be disposed next (adjacent) to a lower side of the display device 10, for example. In an embodiment, the pad area PDA may extend along the first direction DR1.

The connection films 510 may be connected to the wiring pads WPD disposed on a lower side of the non-display area NDA and board pads BPD disposed on an upper side of the circuit board 530. In an embodiment, input terminals, such as bumps, disposed on one side and an opposite side of the connection films 510 may be attached to the wiring pads WPD and the board pads BPD by a film attaching process, for example. In an embodiment, each of the connection films 510 may be bendable like a tape carrier package or a chip on film. The connection films 510 may be bent toward the bottom of the display substrate 100 to reduce a bezel area of the display device 10, for example.

The display drivers 520 may be disposed (e.g., mounted) on the connection films 510. In an embodiment, the display drivers 520 may be implemented as integrated circuits (“ICs”), for example. The display drivers 520 may receive digital video data and a data control signal from the timing controller 540, convert the digital video data into analog data voltages according to the data control signal, and supply the analog data voltages to the data lines DL through the fan out lines.

The circuit board 530 may support the timing controller 540 and the power supply unit 550 and supply signals and power to the display drivers 520. In an embodiment, the circuit board 530 may supply signals supplied from the timing controller 540 and power supply voltages supplied from the power supply unit 550 to the connection films 510 and the display drivers 520 through the board pads BPD in order to display an image in each pixel, for example. To this end, signal lines and power lines may be provided on the circuit board 530.

The timing controller 540 may be disposed (e.g., mounted) on the circuit board 530 and may receive image data and a timing synchronization signal from a display driving system or a graphics device through a user connector provided on the circuit board 530. The timing controller 540 may generate digital video data by arranging the image data according to the pixel arrangement structure based on the timing synchronization signal and supply the generated digital video data to the display drivers 520. The timing controller 540 may generate a data control signal and a gate control signal based on the timing synchronization signal. The timing controller 540 may control the data voltage supply timing of the display drivers 520 based on the data control signal and may control the gate signal supply timing of the gate driver 560 based on the gate control signal.

The power supply unit 550 may be disposed on the circuit board 530 to supply a power supply voltage to the connection films 510 and the display drivers 520. In an embodiment, the power supply unit 550 may generate a driving voltage or a relatively high potential voltage and supply the driving voltage or the relatively high potential voltage to the first voltage lines VDL, may generate a relatively low potential voltage and supply the relatively low potential voltage to the vertical voltage lines VVSL, and may generate an initialization voltage and supply the initialization voltage to the initialization voltage lines VIL, for example.

The gate driver 560 may be disposed on at least any one of left and right sides of the non-display area NDA. The gate driver 560 may generate gate signals based on a gate control signal supplied from the timing controller 540. The gate control signal may include, but is not limited to, a start signal, a clock signal, and a power supply voltage. The gate driver 560 may supply the gate signals to the gate lines GL according to a set order.

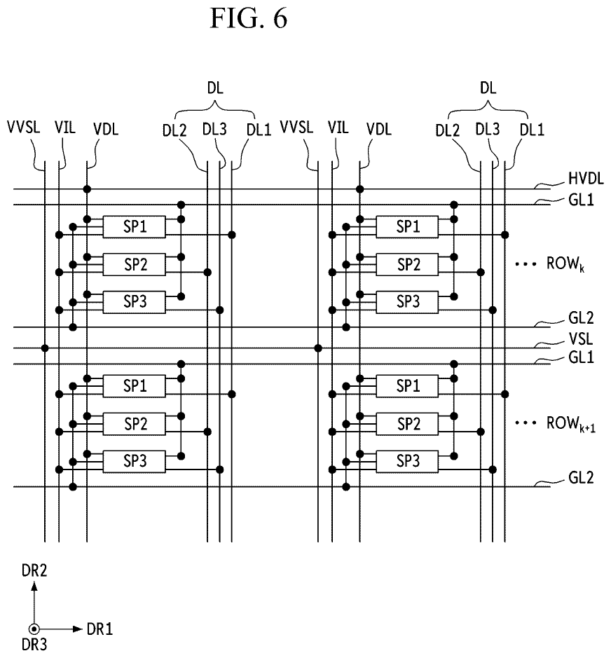

FIG. 6 illustrates pixels and lines of the display device 10 in the embodiment of the specification.

Referring to FIG. 6, the pixels SP may include the first through third pixels SP1 through SP3. The pixel circuits of the first pixels SP1, the pixel circuits of the second pixels SP2, and the pixel circuits of the third pixels SP3 may be sequentially arranged in the direction opposite to the second direction DR2, but the order of the pixel circuits is not limited to this order.

Each of the first through third pixels SP1 through SP3 may be connected to a first voltage line VDL, an initialization voltage line VIL, a gate line GL, and a data line DL.

The first voltage lines VDL may extend in the second direction DR2. The first voltage lines VDL may be disposed on left sides of the pixel circuits of the first through third pixels SP1 through SP3. The first voltage lines VDL may supply driving voltages or relatively high potential voltages to transistors of the first through third pixels SP1 through SP3.

A horizontal voltage line HVDL may extend in the first direction DR1. The horizontal voltage line HVDL may be disposed above a first gate line GL1 disposed in a k^{th} row ROWₖ (where k is a positive integer). The horizontal voltage line HVDL may be connected to the first voltage lines VDL. The horizontal voltage line HVDL may receive driving voltages or relatively high potential voltages from the first voltage lines VDL.

The initialization voltage lines VIL may extend in the second direction DR2. The initialization voltage lines VIL may be disposed on left sides of auxiliary lines branching from each second gate line GL2 in the second direction DR2. The initialization voltage lines VIL may be disposed between the auxiliary lines, which branch from each second gate line GL2 in the second direction DR2, and the vertical voltage lines VVSL. The initialization voltage lines VIL may supply initialization voltages to the respective pixel circuits of the first through third pixels SP1 through SP3. The initialization voltage lines VIL may receive sensing signals from the respective pixel circuits of the first through third pixels SP1 through SP3 and supply the sensing signals to the display drivers 520.

The vertical voltage lines VVSL may extend in the second direction DR2. The vertical voltage lines VVSL may be disposed on left sides of the initialization voltage lines VIL. The vertical voltage lines VVSL may be connected between the power supply unit 550 and a second voltage line VSL. The vertical voltage lines VVSL may supply a relatively low potential voltage received from the power supply unit 550 to the second voltage line VSL.

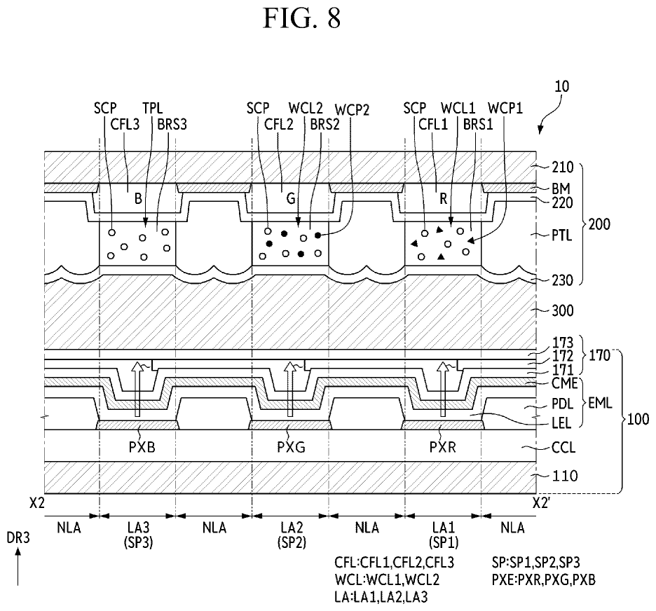

The second voltage line VSL may extend in the first direction DR1. The second voltage line VSL may be disposed above a first gate line GL1 disposed in a (k+1)^{th} row ROWₖ₊₁. The second voltage line VSL may supply a relatively low potential voltage received from the vertical voltage lines VVSL to a light-emitting element layer EML (refer to FIG. 8) of the first through third pixels SP1 through SP3.

The first gate lines GL1 may extend in the first direction DR1. The first gate lines GL1 may be disposed above the pixel circuits of the first pixels SP1. A portion of each first gate line GL1 may branch from the first gate line GL1 to extend in the direction opposite to the second direction DR2. In an embodiment, each of the first gate lines GL1 may include auxiliary lines branching on right sides of the first through third pixels SP1 through SP3 and extending in the direction opposite to the second direction DR2, for example. The auxiliary lines of each of the first gate lines GL1 may be disposed on the right sides of the pixel circuits of the first through third pixels SP1 through SP3. Each of the first gate lines GL1 may supply a first gate signal received from the gate driver 560 to the pixel circuits of the first through third pixels SP1 through SP3 through the auxiliary lines extending in the direction opposite to the second direction DR2.

The second gate lines GL2 may extend in the first direction DR1. The second gate lines GL2 may be disposed below the pixel circuits of the third pixels SP3. A portion of each second gate line GL2 may branch from the second gate line GL2 to extend in the second direction DR2. In an embodiment, each of the second gate lines GL2 may include auxiliary lines branching on left sides of the first voltage lines VDL and extending in the second direction DR2, for example. The auxiliary lines of each of the second gate lines GL2 may be disposed on the left sides of the first voltage lines VDL. Each of the second gate lines GL2 may supply a second gate signal received from the gate driver 560 to the pixel circuits of the first through third pixels SP1 through SP3 through the auxiliary lines extending in the second direction DR2.

The data lines DL may extend in the second direction DR2. The data lines DL may supply data voltages to the pixels SP. The data lines DL may include the first through third data lines DL1 through DL3.

The second data lines DL2 may extend in the second direction DR2. The second data lines DL2 may be disposed on right sides of the auxiliary lines of each first gate line GL1. The second data lines DL2 may supply data voltages received from the display drivers 520 to the pixel circuits of the second pixels SP2.

The third data lines DL3 may extend in the second direction DR2. The third data lines DL3 may be disposed on right sides of the second data lines DL2. The third data lines DL3 may supply data voltages received from the display drivers 520 to the pixel circuits of the third pixels SP3.

The first data lines DL1 may extend in the second direction DR2. The first data lines DL1 may be disposed on right sides of the third data lines DL3. The first data lines DL1 may supply data voltages received from the display drivers 520 to the pixel circuits of the first pixels SP1.

In the drawings, the second data lines DL2, the third data lines DL3, and the first data lines DL1 are sequentially arranged in the first direction DR1. However, the disclosure is not limited to this order. The order in which the first through third data lines DL1 through DL3 are arranged in the first direction DR1 may be variously changed.

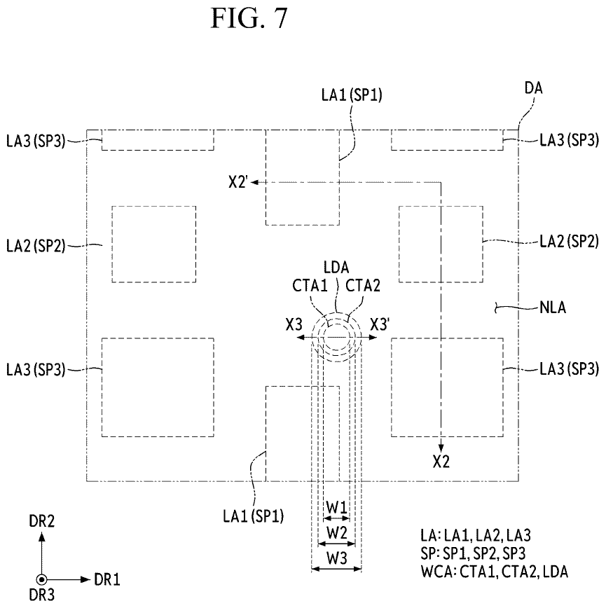

FIG. 7 is a schematic plan view of a part of the display area DA of the display substrate 100.

Referring to FIG. 7, a plurality of emission areas LA and a non-emission area NLA may be defined in the display area DA of the display substrate 100. The emission areas LA may be areas where light generated by light-emitting elements of the display substrate 100 is emitted to the outside of the display substrate 100, and the non-emission area NLA may be an area where light generated by the light-emitting elements of the display substrate 100 is not emitted to the outside of the display substrate 100. In some embodiments, the emission areas LA may include a first emission area LA1, a second emission area LA2, and a third emission area LA3.

In some embodiments, the emission areas LA and the non-emission area NLA may be defined by a pixel defining layer PDL (refer to FIG. 8). In an embodiment, the emission areas LA may be areas overlapping openings of the pixel defining layer PDL (refer to FIG. 8), and the non-emission area NLA may be an area not overlapping the openings of the pixel defining layer PDL (refer to FIG. 8), for example.

In an embodiment, light emitted from the emission areas LA of the display substrate 100 to the color conversion substrate 200 may be light of the third color. In an embodiment, the light of the third color may be blue light and may have a peak wavelength in the range of about 440 nanometers (nm) to about 480 nm, for example. The peak wavelength may refer to a wavelength having maximum intensity in a wavelength region. However, the disclosure is not limited to this example, and the light emitted from the emission areas LA of the display substrate 100 to the color conversion substrate 200 may also be light in an ultraviolet region.

When the first through third emission areas LA1 through LA3 emit light of the same color, the first through third pixels SP1 through SP3 may express various colors through color conversion patterns included in the color conversion substrate 200.

In an embodiment, the first through third emission areas LA1 through LA3 may emit light of different colors. In an embodiment, light emitted from the first emission area LA1 may be red light, light emitted from the second emission area LA2 may be green light, and light emitted from the third emission area LA3 may be blue light, for example.

The first emission area LA1, the second emission area LA2, and the third emission area LA3 may constitute a first pixel SP1, a second pixel SP2, and a third pixel SP3, respectively. The first emission area LA1, the second emission area LA2, and the third emission area LA3 may be repeatedly arranged over the entirety of the display area DA along the first direction DR1 and the second direction DR2. The first emission area LA1, the second emission area LA2, and the third emission area LA3 may constitute one unit color pixel.

In an embodiment, the first emission area LA1 may have a quadrangular shape extending in the first direction DR1 and the second direction DR2. In the drawing, the first emission area LA1 is illustrated as having a quadrangular shape as an example. The second emission area LA2 may have a quadrangular shape extending in a diagonal direction defined by the first direction DR1 and the second direction DR2. In the drawing, the second emission area LA2 is illustrated as having a quadrangular shape as an example. The third emission area LA3 may have a quadrangular shape extending in the first direction DR1 and the second direction DR2. In the drawing, the third emission area LA3 is illustrated as having a quadrangular shape as an example. The shapes of the first through third emission areas LA1 through LA3 are not limited to a quadrangular shape. In an embodiment, the widths and shapes of the first through third emission areas LA1 through LA3 may be different from each other.

The non-emission area NLA may be disposed around the emission areas LA of the display substrate 100 in the display area DA. The non-emission area NLA may be disposed not only around the emission areas LA, but also between the first emission area LA1 and the second emission area LA2, between the second emission area LA2 and the third emission area LA3, and between the third emission area LA3 and the first emission area LA1.

Light emitted from the emission areas LA of the display substrate 100 may pass through light-transmitting areas of the color conversion substrate 200 and then may be provided to the outside of the display device 10.

The non-emission area NLA disposed within the display area DA may include a wiring contact area WCA. The wiring contact area WCA may be an area where an electrode of the light-emitting element layer EML (refer to FIG. 8) and a line of a circuit layer CCL (refer to FIG. 8) are connected and in contact with each other. In an embodiment, the wiring contact area WCA may define openings for connecting the electrode of the light-emitting element layer EML and the line of the circuit layer CCL, for example. In some embodiments, the wiring contact area WCA may include a first contact area CTA1, a second contact area CTA2, and a laser drilling margin area LDA.

FIG. 8 is a cross-sectional view taken along line X2-X2′ of FIG. 7.

Referring to FIG. 8, the display device 10 may include the display substrate 100, the color conversion substrate 200 facing the display substrate 100, and the filler 300 bonding the display substrate 100 and the color conversion substrate 200 together.

The display substrate 100 may include a first substrate 110, the circuit layer CCL, the light-emitting element layer EML, and an encapsulation structure 170.

The first substrate 110 may include a transparent material. In an embodiment, the first substrate 110 may include a transparent insulating material such as glass or quartz. The first substrate 110 may be a rigid substrate, for example. However, the first substrate 110 is not limited to a rigid substrate. The first substrate 110 may also include plastic such as polyimide or may have flexible properties so that it may be curved, bent, folded, or rolled.

The circuit layer CCL (e.g., thin-film transistor layer) may be disposed on the first substrate 110. The circuit layer CCL will be described later.

The light-emitting element layer EML may be disposed on the circuit layer CCL. The light-emitting element layer EML may include pixel electrodes PXE, the pixel defining layer PDL, a light-emitting layer LEL, and a common electrode CME.

The pixel electrodes PXE may be first electrodes, e.g., anodes of light-emitting diodes. The pixel electrodes PXE may have a stacked structure of a material layer having a relatively high work function such as indium-tin-oxide (“ITO”), indium-zinc-oxide (“IZO”), zinc oxide (ZnO) or indium oxide (In₂O₃) and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca) or any combinations thereof. The material layer having a relatively high work function may be disposed on the reflective material layer so that it is disposed close to the light-emitting layer LEL. The pixel electrodes PXE may have, but are not limited to, a multilayer structure of ITO/Mg, ITO/MgF, ITO/Ag, or ITO/Ag/ITO.

The pixel electrodes PXE may include a first pixel electrode PXR, a second pixel electrode PXG, and a third pixel electrode PXB. The first pixel electrode PXR may overlap a first emission area LA1. The second pixel electrode PXG may overlap a second emission area LA2. The third pixel electrode PXB may overlap a third emission area LA3.

The pixel defining layer PDL may be disposed on a surface of the first substrate 110 along the boundaries of the pixels SP. The pixel defining layer PDL may be disposed on the pixel electrodes PXE and may define openings exposing the pixel electrodes PXE. The emission areas LA and the non-emission area NLA may be defined by the pixel defining layer PDL and the openings of the pixel defining layer PDL.

The pixel defining layer PDL may include an organic insulating material such as polyacrylates resin, epoxy resin, phenolic resin, polyamides resin, polyimides resin, unsaturated polyesters resin, polyphenylenethers resin, polyphenylenesulfides resin, or benzocyclobutene (“BCB”). The pixel defining layer PDL may also include an inorganic material.

The light-emitting layer LEL may be disposed on the pixel electrodes PXE exposed by the pixel defining layer PDL. The light-emitting layer LEL may contact not only the pixel electrodes PXE, but also side and upper surfaces of the pixel defining layer PDL. The light-emitting layer LEL may be connected without distinguishing between the emission areas LA and between the pixels SP. The light-emitting layer LEL may be disposed over the entirety of the surface without distinguishing between the emission areas LA and between the pixels SP. Accordingly, the light-emitting layer LEL of the emission areas LA1 through LA3 may emit light having the same wavelength. In an embodiment, the light-emitting layer LEL of the emission areas LA1 through LA3 may emit blue light or ultraviolet light, and the color conversion substrate 200 to be described later may include a wavelength conversion layer WCL, for example. Therefore, each pixel SP may display a corresponding color.

In an embodiment, light-emitting layers LEL may be respectively disposed in the emission areas LA1 through LA3 separated by the pixel defining layer PDL. In this case, the light-emitting layers LEL of the emission areas LA1 through LA3 may emit light having the same wavelength.

In an embodiment in which the display device 10 is an organic light-emitting display device, the light-emitting layer LEL may include an organic layer including an organic material. The organic layer may include an organic light-emitting layer. In some cases, the organic layer may further include at least one of a hole injection layer, a hole transport layer, an electron transport layer, and an electron injection layer as an auxiliary layer for assisting light emission. In an embodiment, when the display device 10 is a micro-LED display device or a nano-LED display device, the light-emitting layer LEL may include an inorganic material such as an inorganic semiconductor.

In some embodiments, the light-emitting layer LEL may have a tandem structure including a plurality of organic light-emitting layers overlapping each other in a thickness direction (e.g., the third direction DR3) and a charge generation layer disposed between the organic light-emitting layers. The organic light-emitting layers overlapping each other may emit light of the same wavelength or may emit light of different wavelengths. At least some layers of the light-emitting layer LEL of each pixel SP may be separated from those of the light-emitting layer LEL of a neighboring pixel SP by the pixel defining layer PDL or may be connected to those of the light-emitting layer LEL of the neighboring pixel SP.

The common electrode CME may be disposed on the light-emitting layer LEL. The common electrode CME may be connected without distinguishing between the emission areas LA and between the pixels SP. The common electrode CME may be a whole-surface electrode disposed over the entirety of the surface without distinguishing between the emission areas LA and between the pixels SP. The common electrode CME may be second electrodes, e.g., cathodes of the light-emitting diodes. The common electrode CME may include a material layer having a relatively small work function such as Li, Ca, LiF/Ca, LiF/Al, Al, Mg, Ag, Pt, Pd, Ni, Au Nd, Ir, Cr, BaF, Ba, or a compound or combination thereof (e.g., a combination of Ag and Mg). The common electrode CME may further include a transparent metal oxide layer disposed on the material layer having a relatively small work function.

The pixel electrodes PXE, the light-emitting layer LEL, and the common electrode CME may constitute light-emitting elements (e.g., organic light-emitting diodes). Light emitted from the light-emitting layer LEL may be output upward through the common electrode CME.

The encapsulation structure 170 may be disposed on the common electrode CME. The encapsulation structure 170 may include at least one thin-film encapsulation layer. In an embodiment, the encapsulation structure 170 may include a first encapsulating inorganic layer 171, an encapsulating organic layer 172, and a second encapsulating inorganic layer 173, for example.

The first encapsulating inorganic layer 171 may be disposed on the light-emitting element layer EML. The first encapsulating inorganic layer 171 may include silicon nitride (SiNₓ), silicon oxide (SiOₓ), or silicon oxynitride (SiOₓN_{y}).

The encapsulating organic layer 172 may be disposed on the first encapsulating inorganic layer 171. The encapsulating organic layer 172 may include an organic insulating material such as polyacrylates resin, epoxy resin, phenolic resin, polyamides resin, polyimides resin, unsaturated polyesters resin, polyphenylenethers resin, polyphenylenesulfides resin, or benzocyclobutene (“BCB”).

The second encapsulating inorganic layer 173 may be disposed on the encapsulating organic layer 172. The second encapsulating inorganic layer 173 may include the same material as that of the first encapsulating inorganic layer 171 described above. In an embodiment, the second encapsulating inorganic layer 173 may include silicon nitride (SiNₓ), silicon oxide (SiOₓ), or silicon oxynitride (SiOₓN_{y}), for example.

In some embodiments, some layers of the encapsulation structure 170 or the entirety of the encapsulation structure 170 may be omitted. When the encapsulation structure 170 is omitted, the filler 300, the sealing portion 400, and the color conversion substrate 200 may be directly disposed on the light-emitting element layer EML. In this case, the filler 300, the sealing portion 400, and the color conversion substrate 200 may perform an encapsulation function.

The color conversion substrate 200 may be disposed on the encapsulation structure 170 to face the display substrate 100. The color conversion substrate 200 may include a second substrate 210, a light-blocking member BM, color filter layers CFL, a first capping layer 220, a partition wall PTL, the wavelength conversion layer WCL, a light-transmitting layer TPL, and a second capping layer 230.

The second substrate 210 may include a transparent material. The second substrate 210 may include a transparent insulating material such as glass or quartz. The second substrate 210 may be a rigid substrate. However, the second substrate 210 is not limited to a rigid substrate. The second substrate 210 may also include plastic such as polyimide or may have flexible properties so that it may be curved, bent, folded, or rolled.

The second substrate 210 may be the same substrate as the first substrate 110, but may have a different material, thickness, and transmittance from the first substrate 110. In an embodiment, the second substrate 210 may have higher transmittance than the first substrate 110, for example. The second substrate 210 may be thicker or thinner than the first substrate 110.

The light-blocking member BM may be disposed on a surface of the second substrate 210, which faces the first substrate 110, along the boundaries of the pixels SP. The light-blocking member BM may overlap the pixel defining layer PDL of the display substrate 100 and may be disposed in the non-emission area NLA. The light-blocking member BM may define openings exposing the surface of the second substrate 210 which overlaps the emission areas LA. The light-blocking member BM may be formed in a lattice shape in a plan view.

The light-blocking member BM may include an organic material. The light-blocking member BM may reduce color distortion due to reflection of external light by absorbing the external light. In addition, the light-blocking member BM may prevent light emitted from the light-emitting layer LEL from intruding into next (adjacent) pixels SP.

In an embodiment, the light-blocking member BM may absorb all visible light wavelengths. The light-blocking member BM may include a light-absorbing material. In an embodiment, the light-blocking member BM may include a material used as a black matrix of the display device 10, for example.

In an embodiment, the light-blocking member BM may absorb light of a predetermined wavelength among the visible light wavelengths and transmit light of another predetermined wavelength. In an embodiment, the light-blocking member BM may include the same material as a color filter layer CFL. Specifically, the light-blocking member BM may include the same material as a blue color filter layer. In some embodiments, the light-blocking member BM may be integrally formed (or unitary) with the blue color filter layer. The light-blocking member BM may also be omitted.

The color filter layers CFL may be disposed on the surface of the second substrate 210 on which the light-blocking member BM is disposed. The color filter layers CFL may be disposed on the surface of the second substrate 210 exposed through the openings of the light-blocking member BM. Further, each of the color filter layers CFL may be disposed on a portion of the neighboring (adjacent) light-blocking member BM.

The color filter layers CFL may include a first color filter layer CFL1 disposed in a first pixel SP1, a second color filter layer CFL2 disposed in a second pixel SP2, and a third color filter layer CFL3 disposed in a third pixel SP3. Each color filter layer CFL may include a colorant such as a dye or pigment that absorbs wavelengths other than a corresponding color wavelength. The first color filter layer CFL1 may be a red color filter layer, the second color filter layer CFL2 may be a green color filter layer, and the third color filter layer CFL3 may be a blue color filter layer. Although neighboring color filter layers CFL are spaced apart from each other on the light-blocking member BM in the drawing, they may also at least partially overlap each other on the light-blocking member BM.

The first capping layer 220 may be disposed on the color filter layers CFL. The first capping layer 220 may prevent damage to or contamination of the color filter layers CFL by preventing penetration of impurities such as moisture or air from the outside into the color filter layers CFL.

The first capping layer 220 may directly contact surfaces of the color filter layers CFL. The first capping layer 220 may include an inorganic material. In an embodiment, the first capping layer 220 may include silicon nitride, aluminum nitride, zirconium nitride, titanium nitride, hafnium nitride, tantalum nitride, silicon oxide, aluminum oxide, titanium oxide, tin oxide, or silicon oxynitride, for example.

The partition wall PTL may be disposed on the first capping layer 220. The partition wall PTL may be disposed in the non-emission area NLA. The partition wall PTL may overlap the light-blocking member BM. The partition wall PTL may define openings exposing the color filter layers CFL. The partition wall PTL may include, but is not limited to, a photosensitive organic material. The partition wall PTL may further include a light-blocking material.

The wavelength conversion layer WCL and/or the light-transmitting layer TPL may be disposed in spaces exposed by the openings of the partition wall PTL. The wavelength conversion layer WCL and the light-transmitting layer TPL may be formed by an inkjet process using the partition wall PTL as a bank, but the disclosure is not limited to this case.

In an embodiment in which the light-emitting layer LEL of each pixel SP emits light of the third color, the wavelength conversion layer WCL may include a first wavelength conversion pattern WCL1 disposed in the first pixel SP1 and a second wavelength conversion pattern WCL2 disposed in the second pixel SP2. The light-transmitting layer TPL may be disposed in the third pixel SP3.

The first wavelength conversion pattern WCL1 may include a first base resin BRS1 and first wavelength conversion materials WCP1 disposed in the first base resin BRS1. The second wavelength conversion pattern WCL2 may include a second base resin BRS2 and second wavelength conversion materials WCP2 disposed in the second base resin BRS2. The light-transmitting layer TPL may include a third base resin BRS3 and scatterers SCP disposed in the third base resin BRS3.

The first through third base resins BRS1 through BRS3 may include a light-transmitting organic material. In an embodiment, the first through third base resins BRS1 through BRS3 may include epoxy resin, acrylic resin, cardo resin, or imide resin, for example. The first through third base resins BRS1 through BRS3 may all include the same material, but the disclosure is not limited to this case.

The scatterers SCP may be metal oxide particles or organic particles. The metal oxide may be, e.g., titanium oxide (TiO₂), zirconium oxide (ZrO₂), aluminum oxide (Al₂O₃), indium oxide (In₂O₃), zinc oxide (ZnO) or tin oxide (SnO₂), and the organic particles may be, e.g., acrylic resin or urethane resin.

The first wavelength conversion materials WCP1 may convert the third color into the first color, and the second wavelength conversion materials WCP2 may convert the third color into the second color. The first wavelength conversion materials WCP1 and the second wavelength conversion materials WCP2 may be quantum dots, quantum rods, or phosphors. The quantum dots may include group IV nanocrystals, group II-VI compound nanocrystals, group III-V compound nanocrystals, group IV-VI nanocrystals, or any combinations thereof. The first wavelength conversion pattern WCL1 and the second wavelength conversion pattern WCL2 may further include scatterers SCP to increase wavelength conversion efficiency.

The light-transmitting layer TPL disposed in the third pixel SP3 may transmit light of the third color emitted from the light-emitting layer LEL while maintaining the wavelength of the light of the third color. The scatterers SCP of the light-transmitting layer TPL may control an output path of light output through the light-transmitting layer TPL. The light-transmitting layer TPL may not include wavelength conversion materials.

The second capping layer 230 may be disposed on the wavelength conversion layer WCL, the light-transmitting layer TPL, and the partition wall PTL. The second capping layer 230 may include an inorganic material. The second capping layer 230 may include a material selected from the materials listed as materials of the first capping layer 220. The second capping layer 230 and the first capping layer 220 may include the same material, but the disclosure is not limited to this case.

The filler 300 may be disposed between the display substrate 100 and the color conversion substrate 200. The filler 300 may fill the space between the display substrate 100 and the color conversion substrate 200 and may bond and couple them to each other. The filler 300 may be disposed between the encapsulation structure 170 of the display substrate 100 and the second capping layer 230 of the color conversion substrate 200. The filler 300 may include, but not limited to, a Si-based organic material or an epoxy-based organic material.

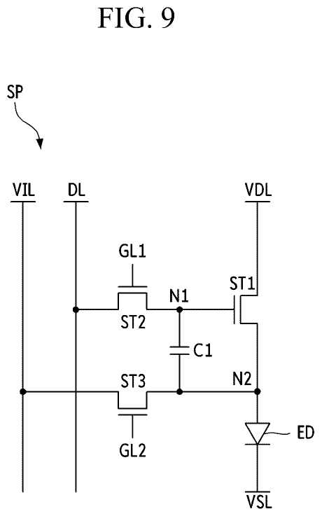

FIG. 9 is an equivalent circuit diagram of a pixel SP in an embodiment of the specification.

Referring to FIG. 9, each pixel SP may be connected to a first voltage line VDL, a data line DL, an initialization voltage line VIL, a first gate line GL1, a second gate line GL2, and a second voltage line VSL.

Each pixel SP may include a pixel circuit and a light-emitting element ED. In an embodiment, as illustrated in the drawing, the pixel circuit of each pixel SP may have a 3T1C structure including three transistors and one capacitor. In an embodiment, the pixel circuit of each pixel SP may include first through third transistors ST1 through ST3 and a capacitor C1, for example. However, the disclosure is not limited to this example, and the number of transistors and capacitors in each pixel circuit may be variously changed. Although the 3T1C structure is described below as an example for ease of description, the disclosure is not limited to the 3T1C structure, and other various modified structures such as a 2T1C structure, a 7T1C structure, a 6T1C structure, and a 17T3C structure are also applicable.

The first transistor ST1 may include a gate electrode, a drain electrode, and a source electrode. The first transistor ST1 may have the gate electrode connected to a first node N1, the drain electrode connected to the first voltage line VDL, and the source electrode connected to a second node N2. The first transistor ST1 may control a drain-source current (or a driving current) based on a data voltage applied to the gate electrode. The first transistor ST1 may be a driving transistor that drives the light-emitting element ED.

The light-emitting element ED may emit light in response to a driving current received. The amount of light emitted from the light-emitting element ED or the luminance of the light-emitting element ED may be proportional to the magnitude of the driving current. The light-emitting element ED may be an organic light-emitting diode including an organic light-emitting layer, a quantum dot light-emitting diode including a quantum dot light-emitting layer, a micro light-emitting diode, or an inorganic light-emitting diode including an inorganic semiconductor.

A first electrode (e.g., pixel electrode) of the light-emitting element ED may be connected to the second node N2, and a second electrode of the light-emitting element ED may be connected to the second voltage line VSL. The first electrode of the light-emitting element ED may be connected to the source electrode of the first transistor ST1, a drain electrode of the third transistor ST3, and a first capacitor electrode of the capacitor C1 through the second node N2.

The second transistor ST2 may be turned on by a first gate signal of the first gate line GL1 to electrically connect the data line DL and the first node N1 which is the gate electrode of the first transistor ST1. The second transistor ST2 may be turned on based on the first gate signal to supply a data voltage to the first node N1. The second transistor ST2 may have a gate electrode connected to the first gate line GL1, a drain electrode connected to the data line DL, and a source electrode connected to the first node N1. The source electrode of the second transistor ST2 may be connected to the gate electrode of the first transistor ST1 and a second capacitor electrode of the capacitor C1 through the first node N1. The second transistor ST2 may be a switching transistor that controls a current flowing to the first transistor ST1 and the light-emitting element ED.

The third transistor ST3 may be turned on by a second gate signal of the second gate line GL2 to electrically connect the initialization voltage line VIL and the second node N2 which is the source electrode of the first transistor ST1. The third transistor ST3 may be turned on based on the second gate signal to supply an initialization voltage to the second node N2. The third transistor ST3 may be turned on based on the second gate signal to supply a sensing signal to the initialization voltage line VIL. The third transistor ST3 may have a gate electrode connected to the second gate line GL2, the drain electrode connected to the second node N2, and a source electrode connected to the initialization voltage line VIL. The drain electrode of the third transistor ST3 may be connected to the source electrode of the first transistor ST1, the first capacitor electrode of the capacitor C1, and the first electrode of the light-emitting element ED through the second node N2. The third transistor ST3 may be a switching transistor that controls a current flowing to the first transistor ST1 and the light-emitting element ED.

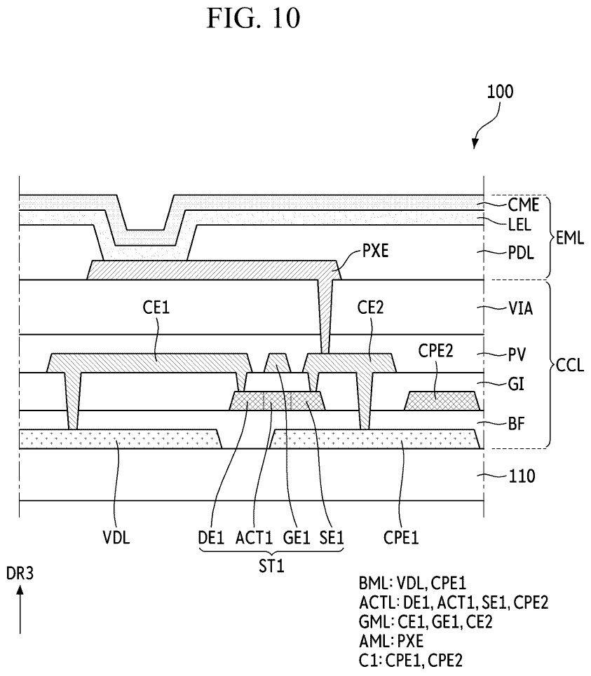

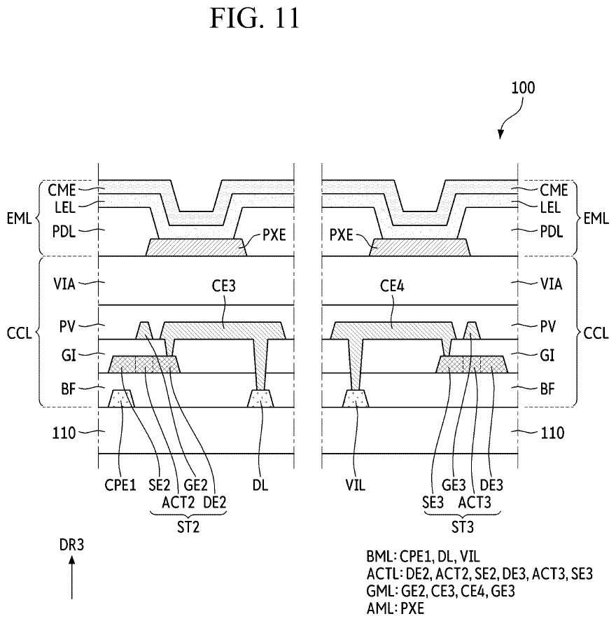

FIG. 10 is a cross-sectional view of an embodiment of the first transistor ST1 of the circuit layer CCL according to the specification. FIG. 11 is a cross-sectional view of an embodiment of the second transistor ST2 and the third transistor ST3 of the circuit layer CCL.

Referring to FIGS. 9, 10 and 11, the display substrate 100 may include the first substrate 110, the circuit layer CCL, and the light-emitting element layer EML.

Since the first substrate 110 has been described above, a description of the first substrate 110 will be omitted.

The circuit layer CCL may be disposed on the first substrate 110. The circuit layer CCL (e.g., thin-film transistor layer) may include a bottom conductive layer BML, a buffer layer BF, an active layer ACTL, a gate insulating layer GI, a gate conductive layer GML, a passivation layer PV, and a via layer VIA. The circuit layer CCL may include the first through third transistors ST1 through ST3 and a capacitor C1.

The bottom conductive layer BML may be disposed on the first substrate 110. The bottom conductive layer BML may include a single layer or a multilayer including any one or more of molybdenum (Mo), aluminum (Al), chromium (Cr), gold (Au), titanium (Ti), nickel (Ni), neodymium (Nd), copper (Cu), and alloys thereof.

In an embodiment, the bottom conductive layer BML may include an initialization voltage line VIL, a data line DL, a first voltage line VDL, a second voltage line VSL, and a first capacitor electrode CPE1 of the capacitor C1.

The buffer layer BF may be disposed on the bottom conductive layer BML. The buffer layer BF may include an inorganic material such as a silicon nitride layer, a silicon oxynitride layer, a silicon oxide layer, a titanium oxide layer, or an aluminum oxide layer. In an alternative embodiment, the buffer layer BF may include a multilayer in which a plurality of layers selected from a silicon nitride layer, a silicon oxynitride layer, a silicon oxide layer, a titanium oxide layer, and an aluminum oxide layer are alternately stacked.

The active layer ACTL may be disposed on the buffer layer BF. The active layer ACTL may include polycrystalline silicon, monocrystalline silicon, low-temperature polycrystalline silicon, amorphous silicon, or an oxide semiconductor material.

In an embodiment, the active layer ACTL may include a first active region ACT1, a first drain electrode DE1 and a first source electrode SE1 of the first transistor ST1, a second active region ACT2, a second drain electrode DE2 and a second source electrode SE2 of the second transistor ST2, a third active region ACT3, a third drain electrode DE3 and a third source electrode SE3 of the third transistor ST3, and a second capacitor electrode CPE2 of the capacitor C1.

The gate insulating layer GI may be disposed on the active layer ACTL. The gate insulating layer GI may include an inorganic layer such as a silicon nitride layer, a silicon oxynitride layer, a silicon oxide layer, a titanium oxide layer, or an aluminum oxide layer.

The gate conductive layer GML may be disposed on the gate insulating layer GI. The gate conductive layer GML may include a single layer or a multilayer including any one or more of molybdenum (Mo), aluminum (Al), chromium (Cr), gold (Au), titanium (Ti), nickel (Ni), neodymium (Nd), copper (Cu), and alloys thereof.

In an embodiment, the gate conductive layer GML may include a first gate line GL1, a second gate line GL2, a first gate electrode GE1 of the first transistor ST1, a second gate electrode GE2 of the second transistor ST2, a third gate electrode GE3 of the third transistor ST3, and connection electrodes CE1 through CE4.

The passivation layer PV may be disposed on the gate conductive layer GML. The passivation layer PV may include an inorganic layer such as a silicon nitride layer, a silicon oxynitride layer, a silicon oxide layer, a titanium oxide layer, or an aluminum oxide layer.

The via layer VIA may be disposed on the passivation layer PV. The via layer VIA may include an organic layer such as acryl resin, epoxy resin, phenolic resin, polyamide resin, or polyimide resin.

The circuit layer CCL may include the first through third transistors ST1 through ST3 and the capacitor C1.

The first transistor ST1 may include the first active region ACT1, the first gate electrode GE1, the first drain electrode DE1, and the first source electrode SE1.

The first active region ACT1 may be disposed in the active layer ACTL. The first active region ACT1 may be overlapped by the first gate electrode GE1 in the third direction DR3. The first active region ACT1 may be a non-conductive region of the active layer ACTL in an area overlapping the first gate electrode GE1.

The first gate electrode GE1 may be disposed in the gate conductive layer GML. The first gate electrode GE1 may be connected to the second source electrode SE2 of the second transistor ST2 and the second capacitor electrode CPE2 of the capacitor C1 through a first node N1.

In the drawings, the first transistor ST1 is illustrated as having a top gate structure in which the first gate electrode GE1 is disposed above the first active region ACT1. However, the disclosure is not limited to a top gate structure. In an embodiment, the first transistor ST1 may also have a bottom gate structure in which the first gate electrode GE1 is disposed below the first active region ACT1, for example. In another embodiment, the first transistor ST1 may have a double gate structure in which the first gate electrode GE1 is disposed both above and below the first active region ACT1.

The first drain electrode DE1 and the first source electrode SE1 may be formed by heat-treating the active layer ACTL to make it conductive. The first drain electrode DE1 and the first source electrode SE1 may be, but are not limited to, P-type semiconductors or N-type semiconductors.

The first drain electrode DE1 may be electrically connected to the first voltage line VDL. In an embodiment, the first drain electrode DE1 may be connected to the first voltage line VDL through a first connection electrode CE1, for example. Accordingly, the first drain electrode DE1 may receive a driving voltage from the first voltage line VDL.

The first source electrode SE1 may be connected to a light-emitting element ED through a second node N2. In an embodiment, the first source electrode SE1 may be connected to a pixel electrode PXE through a second connection electrode CE2, for example. Accordingly, the first source electrode SE1 may supply a driving current to the light-emitting element ED.

The first source electrode SE1 may be connected to the capacitor C1 through the second node N2. In an embodiment, the first source electrode SE1 may be connected to the first capacitor electrode CPE1 of the capacitor C1 through the second connection electrode CE2, for example.

The second transistor ST2 may include the second active region ACT2, the second gate electrode GE2, the second drain electrode DE2, and the second source electrode SE2.

The second active region ACT2 may be disposed in the active layer ACTL. The second active region ACT2 may be overlapped by the second gate electrode GE2 in the third direction DR3. The second active region ACT2 may be a non-conductive region of the active layer ACTL in an area overlapping the second gate electrode GE2.

The second gate electrode GE2 may be disposed in the gate conductive layer GML. The second gate electrode GE2 may be connected to the first gate line GL1. Accordingly, the second gate electrode GE2 may receive a first gate signal from the first gate line GL1.

In the drawings, the second transistor ST2 is illustrated as having a top gate structure in which the second gate electrode GE2 is disposed above the second active region ACT2. However, the disclosure is not limited to a top gate structure. In an embodiment, the second transistor ST2 may also have a bottom gate structure in which the second gate electrode GE2 is disposed below the second active region ACT2, for example. In another embodiment, the second transistor ST2 may have a double gate structure in which the second gate electrode GE2 is disposed both above and below the second active region ACT2.

The second drain electrode DE2 and the second source electrode SE2 may be formed by heat-treating the active layer ACTL to make it conductive. The second drain electrode DE2 and the second source electrode SE2 may be, but are not limited to, P-type semiconductors or N-type semiconductors.

The second drain electrode DE2 may be electrically connected to the data line DL. In an embodiment, the second drain electrode DE2 may be connected to the data line DL through a third connection electrode CE3, for example. Accordingly, the second drain electrode DE2 may receive a data voltage from the data line DL.

The second source electrode SE2 may be connected to the first gate electrode GE1 of the first transistor ST1 through the first node N1. Accordingly, the second source electrode SE2 may supply a data voltage to the first gate electrode GE1 of the first transistor ST1 through the first node N1. The first transistor ST1 may control a driving current based on the data voltage received from the second source electrode SE2.

The second source electrode SE2 may be connected to the capacitor C1 through the first node N1. In an embodiment, although not illustrated in the drawings, the second source electrode SE2 may be connected to the second capacitor electrode CPE2 of the capacitor C1 through a separate connection electrode disposed in the gate conductive layer GML, for example.

The third transistor ST3 may include the third active region ACT3, the third gate electrode GE3, the third drain electrode DE3, and the third source electrode SE3.

The third active region ACT3 may be disposed in the active layer ACTL. The third active region ACT3 may be overlapped by the third gate electrode GE3 in the third direction DR3. The third active region ACT3 may be a non-conductive region of the active layer ACTL in an area overlapping the third gate electrode GE3.

The third gate electrode GE3 may be disposed in the gate conductive layer GML. The third gate electrode GE3 may be connected to the second gate line GL2. Accordingly, the third gate electrode GE3 may receive a second gate signal from the second gate line GL2.

In the drawings, the third transistor ST3 is illustrated as having a top gate structure in which the third gate electrode GE3 is disposed above the third active region ACT3. However, the disclosure is not limited to a top gate structure. In an embodiment, the third transistor ST3 may also have a bottom gate structure in which the third gate electrode GE3 is disposed below the third active region ACT3, for example. In another embodiment, the third transistor ST3 may have a double gate structure in which the third gate electrode GE3 is disposed both above and below the third active region ACT3.

The third drain electrode DE3 and the third source electrode SE3 may be formed by heat-treating the active layer ACTL to make it conductive. The third drain electrode DE3 and the third source electrode SE3 may be, but are not limited to, P-type semiconductors or N-type semiconductors.

The third drain electrode DE3 may be electrically connected to the first source electrode SE1 of the first transistor ST1. In an embodiment, although not illustrated in the drawings, the third drain electrode DE3 may be connected to the first source electrode SE1 of the first transistor ST1 through a separate connection electrode disposed in the gate conductive layer GML, for example.

The third drain electrode DE3 may be connected to the capacitor C1. In an embodiment, although not illustrated in the drawings, the third drain electrode DE3 may be connected to the first capacitor electrode CPE1 of the capacitor C1 through a separate connection electrode disposed in the gate conductive layer GML, for example.

The third source electrode SE3 may be connected to the initialization voltage line VIL. In an embodiment, the third source electrode SE3 may be connected to the initialization voltage line VIL through a fourth connection electrode CE4, for example. Accordingly, the third source electrode SE3 may receive an initialization voltage from the initialization voltage line VIL and supply a sensing signal to the initialization voltage line VIL.

The capacitor C1 may include the first capacitor electrode CPE1 and the second capacitor electrode CPE2.

The first capacitor electrode CPE1 may be disposed in the bottom conductive layer BML. The first capacitor electrode CPE1 may be connected to the first source electrode SE1 of the first transistor ST1 through the second connection electrode CE2. The first capacitor electrode CPE1 may be connected to the third drain electrode DE3 of the third transistor ST3 through a separate connection electrode disposed in the gate conductive layer GML.

The second capacitor electrode CPE2 may be disposed in the active layer ACTL. The second capacitor electrode CPE2 may be connected to the first gate electrode GE1 of the first transistor ST1 through a separate connection electrode disposed in the gate conductive layer GML. The second capacitor electrode CPE2 may be connected to the second source electrode SE2 of the second transistor ST2 through a separate connection electrode disposed in the gate conductive layer GML.

The light-emitting element layer EML may include an anode conductive layer AML, the pixel defining layer PDL, the light-emitting layer LEL, and the common electrode CME.

The anode conductive layer AML may be disposed on the circuit layer CCL. In an embodiment, the anode conductive layer AML may be disposed on the via layer VIA, for example. In an embodiment, the anode conductive layer AML may include the pixel electrode PXE.

The anode conductive layer AML may have a stacked structure of a material layer having a relatively high work function such as indium-tin-oxide (“ITO”), indium-zinc-oxide (“IZO”), zinc oxide (ZnO) or indium oxide (In₂O₃) and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca) or any combinations thereof. The material layer having a relatively high work function may be disposed on the reflective material layer so that it is disposed close to the light-emitting layer LEL. The pixel electrode PXE may have, but is not limited to, a multilayer structure of ITO/Mg, ITO/MgF, ITO/Ag, or ITO/Ag/ITO.

In the display device 10 in the illustrated embodiment, the number of layers included in the circuit layer CCL is minimized to reduce the number of masks desired to pattern each layer. Accordingly, process efficiency may be improved.

In an embodiment, lines such as the data lines DL, the initialization voltage lines VIL, the first voltage lines VDL and the second voltage lines VSL are placed in the bottom conductive layer BML, and lines such as the gate lines GL, the horizontal voltage lines HVDL and the second voltage lines VSL are placed in the gate conductive layer GML, for example. Therefore, since a layer for placing the lines is not added, the number of layers may be minimized.

In another embodiment, the first capacitor electrode CPE1 is placed in the bottom conductive layer BML, and the second capacitor electrode CPE2 is placed in the active layer ACTL. Therefore, since a layer for placing the capacitor C1 is not added, the number of layers may be minimized.

In another embodiment, connection electrodes for connecting the bottom conductive layer BML, the active layer ACTL, and the gate conductive layer GML are placed in the gate conductive layer GML. Therefore, since a layer for placing the connection electrodes is not added, the number of layers may be minimized.

In the display device 10 in the illustrated embodiment, since the number of layers included in the circuit layer CCL is minimized, a distance between the light-emitting element layer EML and the bottom conductive layer BML in the third direction DR3 may be reduced. Accordingly, a distance between the lines such as the data lines DL, the initialization voltage lines VIL, the first voltage lines VDL and the second voltage lines VSL and the electrodes of the light-emitting element layer EML such as the pixel electrodes PXE and the common electrode CME may be reduced. In addition, the number of connection electrodes for connecting the lines and the electrodes may be reduced. Accordingly, an IR-drop phenomenon in which a voltage provided from the lines to the electrodes drops may be minimized.

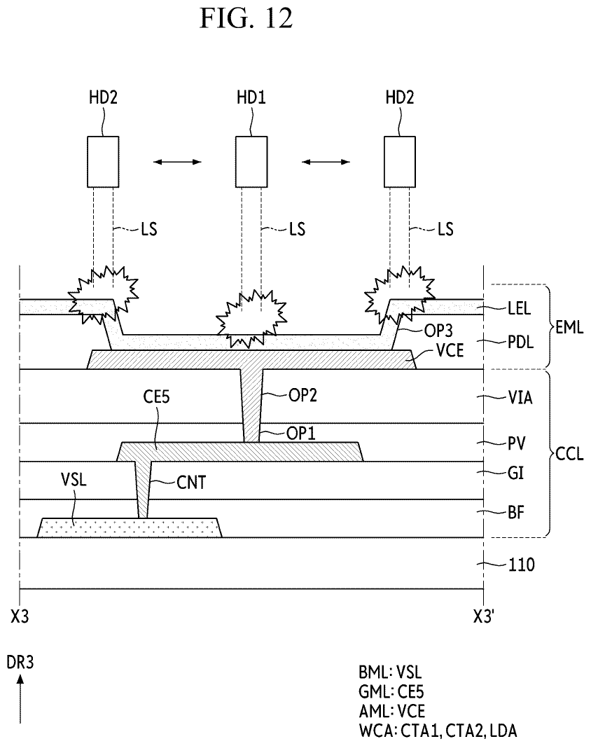

FIG. 12 is a cross-sectional view illustrating a process of removing a portion of the light-emitting layer LEL through a laser drilling process.

Referring to FIG. 12, the bottom conductive layer BML may further include a second voltage line VSL. The gate conductive layer GML may further include a fifth connection electrode CE5. The anode conductive layer AML may further include an auxiliary electrode VCE.

The second voltage line VSL may receive a relatively low potential voltage from a vertical voltage line VVSL (refer to FIG. 6). The second voltage line VSL may be connected to the fifth connection electrode CE5. The fifth connection electrode CE5 may connect the second voltage line VSL and the auxiliary electrode VCE. The auxiliary electrode VCE may connect the fifth connection electrode CE5 and the common electrode CME. The second voltage line VSL may provide a relatively low potential voltage to the common electrode CME through the fifth connection electrode CE5 and the auxiliary electrode VCE.

The display substrate 100 may include a wiring contact area WCA. The wiring contact area WCA may be an area where an electrode of the light-emitting element layer EML and a line of the circuit layer CCL are connected and in contact with each other. In an embodiment, as illustrated in FIG. 12, the second voltage line VSL may be connected to the common electrode CME through the fifth connection electrode CE5 and the auxiliary electrode VCE in the wiring contact area WCA, for example.

In some embodiments, a contact hole CNT, a first opening OP1, a second opening OP2, a third opening OP3, and a fourth opening may be defined in the display device.

The contact hole CNT may penetrate the buffer layer BF and the gate insulating layer GI. The contact hole CNT may expose at least a portion of an upper surface of the second voltage line VSL. The second voltage line VSL and the fifth connection electrode CE5 may be connected to each other through the contact hole CNT. The contact hole CNT may be defined through a photolithography process when the buffer layer BF and the gate insulating layer GI are formed. In some embodiments, when the second voltage line VSL is directly connected to the auxiliary electrode VCE without the fifth connection electrode CE5, the contact hole CNT may be omitted.

The first opening OP1 may penetrate the passivation layer PV. The first opening OP1 may expose at least a portion of an upper surface of the fifth connection electrode CE5. The auxiliary electrode VCE and the fifth connection electrode CE5 may be connected to each other through the first opening OP1. The first opening OP1 may be defined through a photolithography process when the passivation layer PV is formed.

The second opening OP2 may penetrate the via layer VIA. The second opening OP2 may expose at least a portion of the upper surface of the fifth connection electrode CE5. The auxiliary electrode VCE and the fifth connection electrode CE5 may be connected to each other through the first opening OP1 and the second opening OP2. The second opening OP2 may be defined through a photolithography process when the via layer VIA is formed. A first contact area CTA1 where the auxiliary electrode VCE and the fifth connection electrode CE5 contact each other may be formed by the second opening OP2.

In some embodiments, when the second voltage line VSL is directly connected to the auxiliary electrode VCE without the fifth connection electrode CE5, the auxiliary electrode VCE and the second voltage line VSL may be connected to each other through the first opening OP1 and the second opening OP2. In some embodiments, a width of the first opening OP1 may be smaller than a width of the second opening OP2, but the disclosure is not limited to this embodiment.

The third opening OP3 may penetrate the pixel defining layer PDL. The third opening OP3 may expose at least a portion of an upper surface of the auxiliary electrode VCE. The common electrode CME and the auxiliary electrode VCE may be connected to each other through the third opening OP3. The third opening OP3 may be defined through a photolithography process when the pixel defining layer PDL is formed. A laser drilling margin area LDA where the light-emitting layer LEL and the auxiliary electrode VCE contact each other and where a portion of the light-emitting layer LEL is removed may be formed by the third opening OP3.

The light-emitting layer LEL may be removed by a laser drilling process. In an embodiment, an intense-light generator, e.g., a laser generator (HD1, HD2) may irradiate intense light, e.g., laser light LS to a portion of the light-emitting layer LEL, for example. The light-emitting layer LEL in an area irradiated with the laser light LS may be removed by the energy of the laser light LS. In an embodiment, a wavelength of the laser light LS may be about 300 nm to 400 nm. In an embodiment, output energy per unit area of the laser light LS may be about 200 millijoules per square centimeter (mJ/cm²).

The laser generator (HD1, HD2) may irradiate the laser light LS from a first position HD1 or irradiate the laser light LS from a second position HD2. In an embodiment, the laser generator (HD1, HD2) may irradiate the laser light LS from the first position HD1. However, due to an error occurring during a process, the laser light LS may also be irradiated from the second position HD2.

The specification may correct an error occurring in a detection process due to the laser light LS being irradiated to a different position depending on the position of the laser generator (HD1, HD2) in a process of manufacturing a display device. The laser light LS should be irradiated from the first position HD1. However, when the laser light LS is irradiated from the second position HD2 or the like which is different from the first position HD1, the light-emitting layer LEL may not be removed from a designed position.

The auxiliary electrode VCE may contact the common electrode CME to be placed later. When the light-emitting layer LEL corresponding to the second position HD2 is removed by the laser light LS irradiated from the second position HD2, a contact area between the auxiliary electrode VCE and the common electrode CME is not sufficiently secured. Even in this case, however, in some embodiments, the contact area should be treated as being sufficiently secured, and in other embodiments, the contact area should be treated as not being sufficiently secured. The specification may provide a manufacturing process, a manufacturing method or a manufacturing system which may determine whether the contact area has been sufficiently secured and may provide a display device manufactured according to the manufacturing process, the manufacturing method or the manufacturing system.

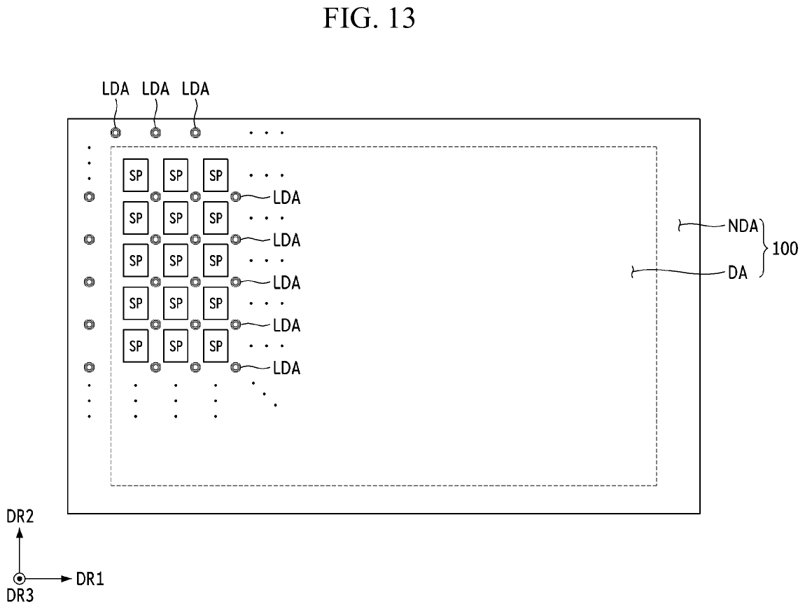

FIG. 13 is a plan view illustrating positions at which laser drilling margin areas LDA are disposed.

Referring to FIG. 13, laser drilling margin areas LDA in an embodiment may be formed in the display area DA and the non-display area NDA. Each of the laser drilling margin areas LDA may be an area where an auxiliary electrode including an upper surface exposed by the pixel defining layer is disposed. Each of the laser drilling margin areas LDA may include an area where the auxiliary electrode and the common electrode contact each other. In the case of a display device including a relatively large display panel, a width of a line disposed in the display area DA may increase, and parasitic resistance within the line may increase. The common electrode is disposed over the entirety of the surface in at least a part of the display area DA. As the length of the line increases, a value of a common voltage transmitted through the common electrode may not be constant throughout the display area DA due to a voltage drop, etc. In the display device in the embodiment, since the auxiliary electrode and the common electrode contact each other, the voltage drop phenomenon described above may be improved. In addition, since there is no need to increase the voltage applied to the common electrode, power consumption may be improved.

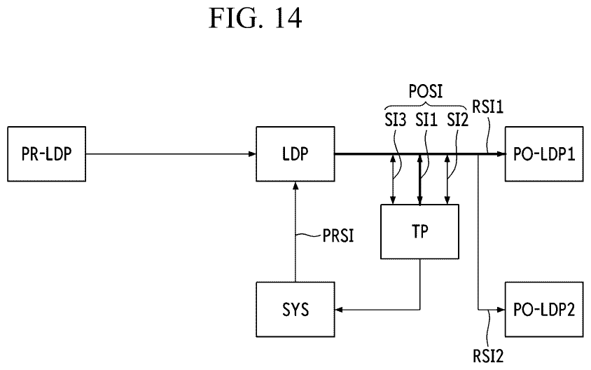

FIG. 14 is a block diagram illustrating a system in which a method of manufacturing a display device in an embodiment of the specification is implemented.

Referring to FIG. 14, a laser drilling process may be a process for removing at least a portion of a light-emitting layer. The manufacturing method in the embodiment of the specification may include a processing unit LDP in which an operation of performing the laser drilling process is performed, a pre-processing unit PR-LDP in which an operation before the laser drilling process is performed, and a post-processing unit (PO-LDP1, PO-LDP2) in which an operation after the laser drilling process is performed. In the pre-processing unit PR-LDP, an operation to be performed before the processing unit LDP in which at least a portion of the light-emitting layer is removed may be performed. In the post-processing unit (PO-LDP1, PO-LDP2), an operation to be performed after the processing unit LDP may be performed. The post-processing unit (PO-LDP1, PO-LDP2) may include a first post-processing unit PO-LDP1 and a second post-processing unit PO-LDP2.

After the laser drilling process is performed, a detection operation may be performed by a detection unit TP. The detection unit TP may perform an operation of checking whether laser light has been properly irradiated to an appropriate location and determining whether a sufficient contact area has been secured between an auxiliary electrode and a common electrode. In an embodiment, the detection unit TP may inspect a display device in which at least a portion of the light-emitting layer has been removed and may determine whether to proceed to an operation performed in the first post-processing unit PO-LDP1 or an operation performed in the second post-processing unit PO-LDP2. In an embodiment, the detection unit TP may transmit a post-signal POSI. The post-signal POSI is a signal that determines whether to proceed to the operation performed in the first post-processing unit PO-LDP1 or the operation performed in the second post-processing unit PO-LDP2.

The post-signal POSI may include a first post-signal SI1, a second post-signal SI2, and a third post-signal SI3. A display device which receives the first post-signal SI1 proceeds to the operation performed in the first post-processing unit PO-LDP1. A display device which receives the second post-signal SI2 proceeds to the operation performed in the second post-processing unit PO-LDP2.

A first response path RSI1 may be performed for the first post-signal SI1. A second response path RSI2 may be performed for the second post-signal SI2. When the first response path RSI1 is performed, the operation performed in the first post-processing unit PO-LDP1 is performed. When the second response path RSI2 is performed, the operation performed in the second post-processing unit PO-LDP2 is performed.

The detection unit TP performs the detection operation as described above. While the post-signal POSI is a signal that determines which operation to perform on an already manufactured display device as a result of the detection operation, a pre-signal PRSI is a signal that includes information to be corrected in the processing unit LDP as a result of the detection operation.

The pre-signal PRSI may be output from a system unit SYS connected to the detection unit TP and may be transmitted to the processing unit LDP. The pre-signal PRSI may include a signal that improves the accuracy of the drilling process performed in the processing unit LDP so that laser light may be irradiated to an appropriate location based on the detection result of the detection unit TP. In an embodiment, the pre-signal PRSI may include a signal for applying an offset to the position of a laser generator or a signal for correcting the size and/or position of laser light, for example, but the disclosure of the specification is not limited to this embodiment. The signal for correcting the size of the laser light may include a correction signal related to whether the light-emitting layer has been removed with an appropriate output energy. In an embodiment, the signal for correcting the size of the laser light may include a correction signal for an output energy value of the laser light, a correction signal related to whether the light-emitting layer has been removed to an appropriate thickness, etc., for example. The signal for correcting the position of the laser light may include a signal related to position adjustment using an align key, but the disclosure of the specification is not limited to this embodiment.

After the operation performed in the processing unit LDP is performed, the post-signal POSI may be output from the detection unit TP, or the pre-signal PRSI may be output from the system unit SYS connected to the detection unit TP. The pre-signal PRSI may include a signal for correcting factors before the laser drilling process is performed, and the post-signal POSI may include a signal for correcting factors after the laser drilling process is performed.

The method of manufacturing the display device according to the specification may provide a solution to a problem caused by the reception of the post-signal POSI.

The post-signal POSI may include the first post-signal SI1, the second post-signal SI2, and the third post-signal SI3. The first post-signal SI1 causes the first response path RSI1, and an operation performed in the first post-processing unit PO-LDP1 is performed on a manufactured display device according to the first response path RSI1. The second post-signal SI2 causes the second response path RSI2, and an operation performed in the second post-processing unit PO-LDP2 is performed on a manufactured display device according to the second response path RSI2. The third post-signal SI3 will be described later.

The operation performed in the first post-processing unit PO-LDP1 and the operation performed in the second post-processing unit PO-LDP2 may be different from each other. In an embodiment, in a display device on which the operation performed in the first post-processing unit PO-LDP1 is to be performed, the contact area between the auxiliary electrode and the common electrode may be sufficiently secured, for example. Therefore, the first post-processing unit PO-LDP1 may perform an operation that must be performed after the laser drilling process to manufacture the display device, such as depositing the common electrode.

In a display device on which the operation performed in the second post-processing unit PO-LDP2 is to be performed, the contact area between the auxiliary electrode and the common electrode may not be sufficiently secured. Therefore, the second post-processing unit PO-LDP2 may perform an operation that must be performed when the common electrode is not deposited or when the display device is determined to be defective.

A display device to which the first post-signal SI1 is output from the detection unit TP will now be described.

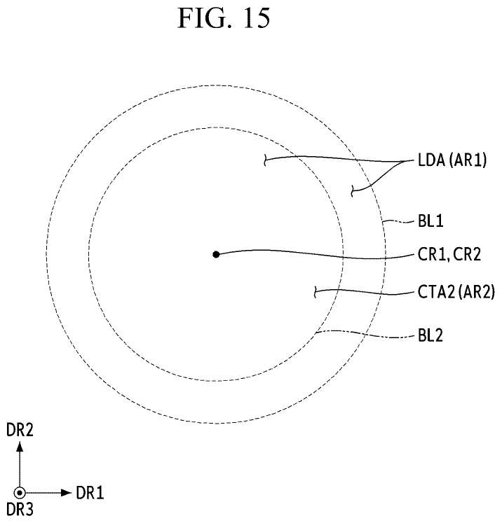

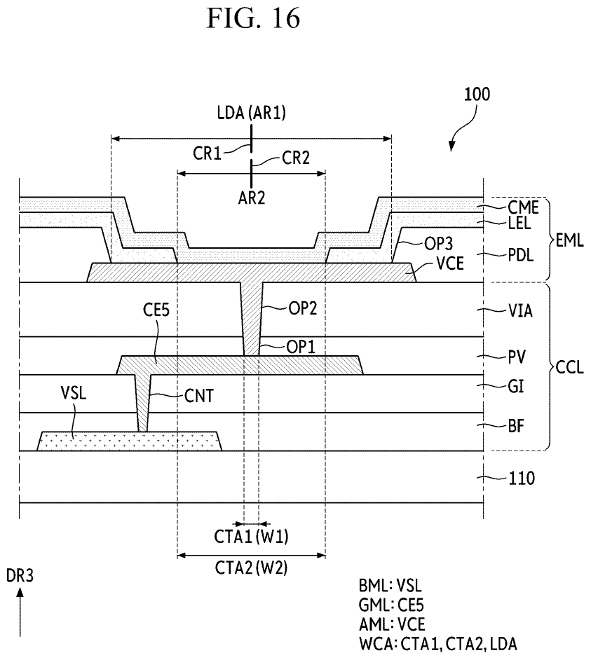

FIG. 15 is a plan view of a display device in embodiments of the specification. FIG. 16 is a cross-sectional view corresponding to FIG. 15. FIG. 16 is also a cross-sectional view taken along line X2-X2′ of FIG. 7.

Referring to FIGS. 15 and 16, a display device to which the first post-signal SI1 is output may include a substrate 110 including a first area AR1 and a second area AR2. The first area AR1 may include an area exposed by a pixel defining layer PDL on an upper surface of an auxiliary electrode VCE. The second area AR2 may include an area exposed by a light-emitting layer LEL on the upper surface of the auxiliary electrode VCE. The display device to which the first post-signal SI1 is output may be a display device formed by irradiating laser light from a first position using a laser generator.

A laser drilling margin area LDA may be substantially the same as the first area AR1. A first boundary BL1 may be defined based on a boundary of the first area AR1, and a first center CR1 may be defined from a center of the first area AR1. A second boundary BL2 may be defined based on a boundary of the second area AR2, and a second center CR2 may be defined from a center of the second area AR2. Each of the first boundary BL1 and the second boundary BL2 may be shaped like a closed curve or a polygon. In an embodiment, each of the first boundary BL1 and the second boundary BL2 may be a closed curve, an oval, or a circle. However, the disclosure of the specification is not limited to these shapes.

In the display device to which the first post-signal SI1 is output, the first boundary BL1 may not include a plurality of points overlapping the second boundary BL2. In other words, the second area AR2 may be included in the first area AR1. When laser light is irradiated by the laser generator disposed at the first position, the first center CR1 and the second center CR2 may overlap in the third direction DR3 of the substrate 110. However, even when the first center CR1 and the second center CR2 do not overlap, the second area AR2 may be included in the first area AR1. Therefore, the disclosure of the specification is not limited to whether the first center CR1 and the second center CR2 overlap.

When the second area AR2 is included in the first area AR1, a contact area (e.g., a second contact area CTA2) between the auxiliary electrode VCE and a common electrode CME may be sufficiently secured. Therefore, the display device to the first post-signal SI1 is output may sufficiently improve power consumption.

A wiring contact area WCA may include the first area AR1, the second area AR2, a first contact area CTA1, the second contact area CTA2, and the laser drilling margin area LDA.

The pixel defining layer PDL may cover an end of the auxiliary electrode VCE to expose at least a portion of the upper surface of the auxiliary electrode VCE. The light-emitting layer LEL may be disposed on an anode conductive layer AML including the auxiliary electrode VCE to expose at least a portion of the upper surface of the auxiliary electrode VCE.

The first area AR1 may include an area exposed by the pixel defining layer PDL on the upper surface of the auxiliary electrode VCE. In an embodiment, the first area AR1 may be substantially the same as the laser drilling margin area LDA.

The second area AR2 may include an area exposed by the light-emitting layer LEL on the upper surface of the auxiliary electrode VCE. In the display device to which the first post-signal SI1 is output, the second area AR2 and the second contact area CTA2 may be substantially the same.

The first contact area CTA1 may be an area where the auxiliary electrode VCE contacts a second voltage line VSL or an area where the auxiliary electrode VCE contacts a connection electrode connecting the second voltage line VSL and the auxiliary electrode VCE. In an embodiment, when the auxiliary electrode VCE is connected to the second voltage line VSL through a fifth connection electrode CE5, the first contact area CTA1 may be an area where the auxiliary electrode VCE and the fifth connection electrode CE5 directly contact each other, for example. In another embodiment, when the auxiliary electrode VCE is directly connected to the second voltage line VSL without the fifth connection electrode CE5, the first contact area CTA1 may be an area where the auxiliary electrode VCE and the second voltage line VSL directly contact each other.

The second contact area CTA2 may be an area where the common electrode CME contacts the auxiliary electrode VCE. In an embodiment, the second contact area CTA2 may be an area where a portion of the light-emitting layer LEL is removed so that the common electrode CME directly contacts the auxiliary electrode VCE, for example. In the display device to which the first post-signal SI1 is output, the second area AR2 and the second contact area CTA2 may be substantially the same.

The wiring contact area WCA may define openings for connecting an electrode of a light-emitting element layer EML and a line of a circuit layer CCL. In an embodiment, the wiring contact area WCA may define openings defined in a non-conductive layer for connecting the second voltage line VSL and the common electrode CME, for example.

A fourth opening may penetrate the light-emitting layer LEL. The fourth opening may expose at least a portion of the upper surface of the auxiliary electrode VCE. The common electrode CME and the auxiliary electrode VCE may be connected to each other through the fourth opening. The fourth opening may be defined through a laser drilling process. The second contact area CTA2 where the auxiliary electrode VCE and the fifth connection electrode CE5 contact each other may be formed by the fourth opening.

In some embodiments, a width W1 of the first contact area CTA1 and a width W2 of the second contact area CTA2 may each be smaller than a width of the laser drilling margin area LDA. In the specification, the width W1 of the first contact area CTA1 may mean a minimum width of a second opening OP2, the width W2 of the second contact area CTA2 may mean a minimum width of the fourth opening, and the width of the laser drilling margin area LDA may mean a minimum width of a third opening OP3.

In an embodiment, the width of the laser drilling margin area LDA may be about 20 micrometers (μm) or more. Preferably, the width of the laser drilling margin area LDA may be about 30 μm or more. In an embodiment, the width W1 of the first contact area CTA1 and the width W2 of the second contact area CTA2 may be about 5 μm to 30 μm.

In some embodiments, the first contact area CTA1 and the second contact area CTA2 may each overlap the laser drilling margin area LDA in the third direction DR3. In an embodiment, the second opening OP2 of a via layer VIA and the fourth opening of the light-emitting layer LEL may each overlap the third opening OP3 of the pixel defining layer PDL in the third direction DR3, for example. The entirety of the first contact area CTA1 and the entirety of the second contact area CTA2 may each be disposed within an area overlapping the laser drilling margin area LDA.

Accordingly, the width of the laser drilling margin area LDA may be secured to the maximum within the same width of the wiring contact area WCA. Therefore, a laser drilling process margin may be secured even in a high-resolution panel.

The laser drilling margin area LDA may be an area for securing a process margin of laser light LS in a laser drilling process. The laser drilling margin area LDA may include an area where the light-emitting layer LEL contacts the auxiliary electrode VCE and an area where the light-emitting layer LEL is removed. In an embodiment, the laser drilling margin area LDA may include the area where the light-emitting layer LEL contacts the auxiliary electrode VCE and the second contact area CTA2, for example.

A display device to which the second post-signal SI2 is output will now be described.

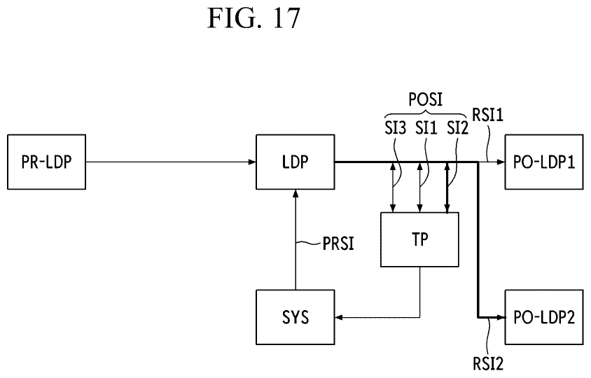

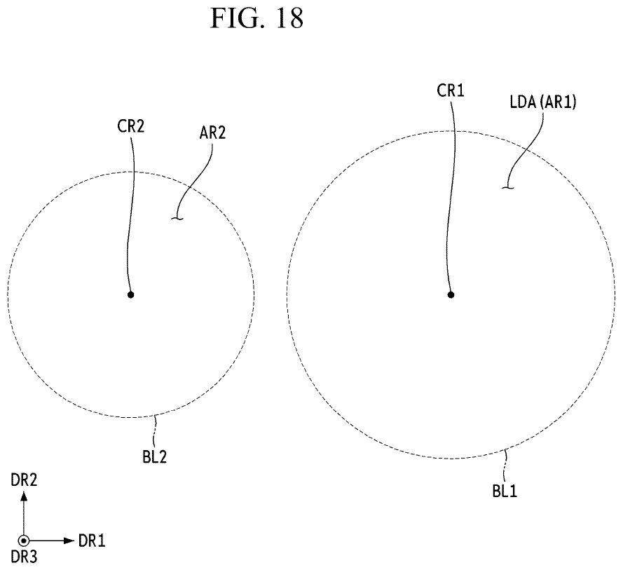

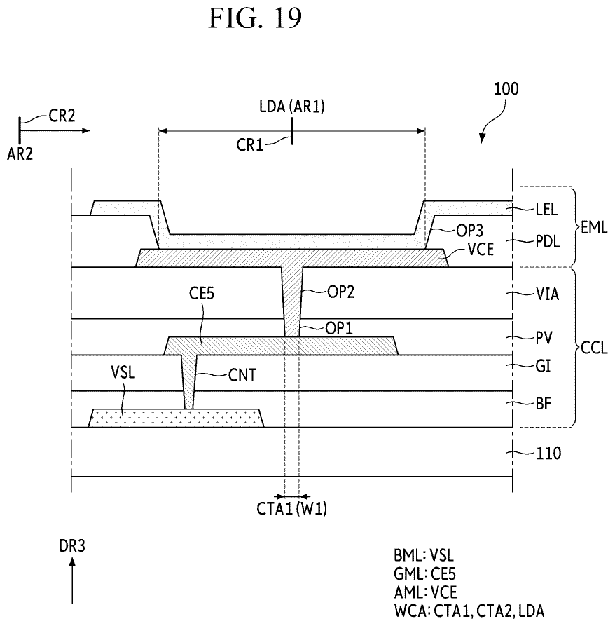

FIG. 17 is a block diagram illustrating a system in which a method of manufacturing a display device in an embodiment of the specification is implemented. FIG. 18 is a plan view of a display device in embodiments of the specification. FIG. 19 is a cross-sectional view corresponding to FIG. 18.

Referring to FIGS. 17, 18 and 19, in a display device to which the second post-signal SI2 is output, a first boundary BL1 may not include a plurality of points overlapping a second boundary BL2. In other words, a second area AR2 may not overlap a first area AR1. When laser light is irradiated by the laser generator disposed at a second position, a first center CR1 and a second center CR2 may be misaligned in the third direction DR3 of a substrate. The entirety of the second area AR2 may not overlap the first area AR1 in the thickness direction (e.g., the third direction DR3). Therefore, a second contact area CTA2 does not exist, and the display device to which the second post-signal SI2 is output cannot relatively improve power consumption. An operation performed in a second post-processing unit PO-LDP2 is performed on the display device to which the second post-signal SI2 is output. The second post-processing unit PO-LDP2 may not deposit a common electrode or may perform an operation of determining whether an appropriate contact area (e.g., the second contact area CTA2) has been secured over the entirety of the display area including a plurality of laser drilling margin areas LDA. When the contact area (e.g., the second contact area CTA2) is not sufficiently secured in any one of the laser drilling margin areas LDA, the voltage drop phenomenon of the display device may not be improved in the display area including the corresponding laser drilling margin area LDA. For the display device including the corresponding laser drilling margin area LDA, the second post-processing unit PO-LDP2 may perform a follow-up process such as removing a light-emitting layer LEL and re-performing the laser drilling process, but the disclosure of the specification is not limited to this embodiment.

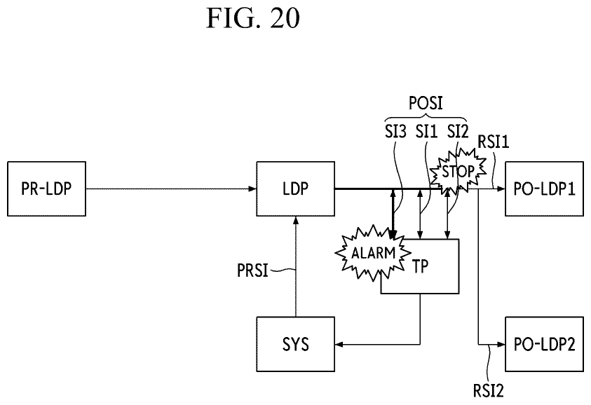

FIG. 20 is a block diagram illustrating a system in which a method of manufacturing a display device in an embodiment of the specification is implemented.

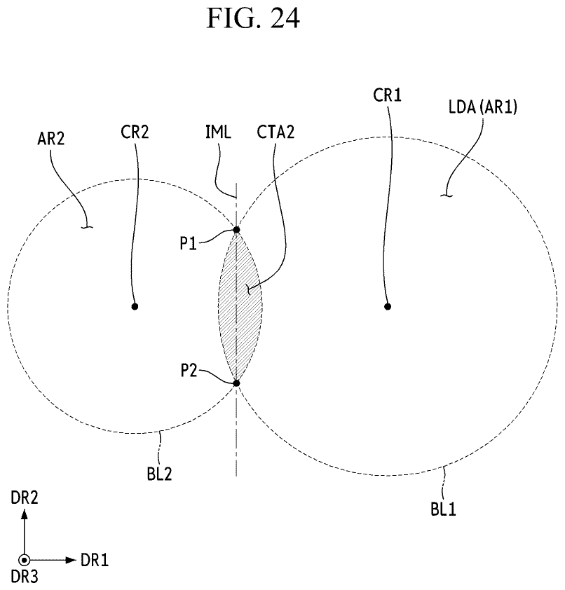

Referring to FIG. 20, when a display device, to which a third post-signal SI3 is to be output, is manufactured, a detection unit TP may not be able to clearly determine whether an appropriate contact area (e.g., a second contact area CTA2) has been secured or has not been secured. The detection unit TP clearly outputs a first post-signal SI1 when the entirety of the second area AR2 overlaps a first area AR1. When the entirety of the second area AR2 does not overlap (is misaligned) with the first area AR1, the detection unit TP clearly outputs a second post-signal SI2. However, when an overlapping area (e.g., the second contact area CTA2) between the second area AR2 and the first area AR1 is smaller than the second area AR2 (refer to FIGS. 24, 25, 27, 28, 29 and 30), the detection unit TP may output the third post-signal SI3.

When the third post-signal SI3 is output, a recognition signal including an alarm may be generated in a manufacturing process. However, the disclosure of the specification is not limited to this embodiment. The recognition signal is a signal output from the detection unit TP when it is relatively difficult to make a clear judgment. The recognition signal includes visual and auditory signals. The recognition signal may be omitted. When the third post-signal SI3 is output, a process may be stopped.

In this case, in the manufacturing process in the embodiment, operations of a manufacturing method according to a flowchart described below may be performed.

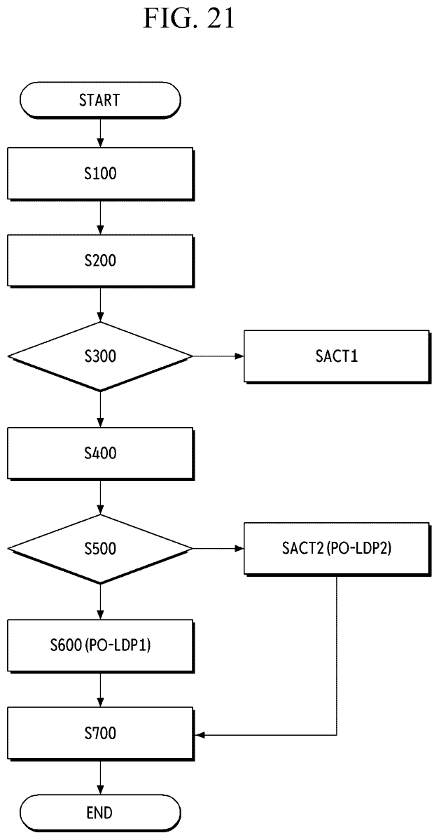

FIG. 21 is a flowchart illustrating a system in which a method of manufacturing a display device in an embodiment of the specification is implemented.

Referring to FIG. 21, in one operation, a recognition signal may be generated (refer to S100). The operation of generating the recognition signal may be omitted.

In a next operation, an operation of identifying the cause of generation of the recognition signal may be performed (refer to S200).

In a next operation, it may be determined whether the recognition signal has been generated because it was impossible to determine the positional relationship between a first area AR1 and a second area AR2 (refer to S300).

When it is determined that the recognition signal has been generated not because it was impossible to determine the positional relationship, an operation of identifying the cause of generation of the recognition signal and taking measures for the identified cause may be performed (refer to SACT1).

When it is determined that the recognition signal has been generated because it was impossible to determine the positional relationship, a next operation may be performed (refer to S400). Here, an operation of identifying an image in which the first area AR1 and the second area AR2 are formed may be performed.

In a next operation, an operation of detecting the position of the first area AR1 and the position of the second area AR2 may be performed (refer to S500). A detection determination process will be described in detail later.

After the positional relationship between the first area AR1 and the second area AR2 is determined, any one of a plurality of operations (refer to SACT2 and S600) may be performed. When the determination of the positional relationship is performed in advance, it may be determined whether a display device is one in which a contact area (e.g., a second contact area CTA2) may be appropriately secured or one in which the contact area cannot be appropriately secured.

When it is determined that the contact area (e.g., the second contact area CTA2) has been appropriately secured despite the generation of the recognition signal, a first response path RSI1 may be performed according to a third post-signal SI3, and an operation performed in a first post-processing unit PO-LDP1 may be performed on a manufactured display device (refer to S600).

When it is determined that the recognition signal has been generated because the contact area (e.g., the second contact area CTA2) could not be appropriately secured, a second response path RSI2 may be performed according to the third post-signal SI3, and an operation performed in a second post-processing unit PO-LDP2 may be performed on the manufactured display device (refer to SACT2).

In a next operation, an operation of restarting a stopped process may be performed (refer to S700).

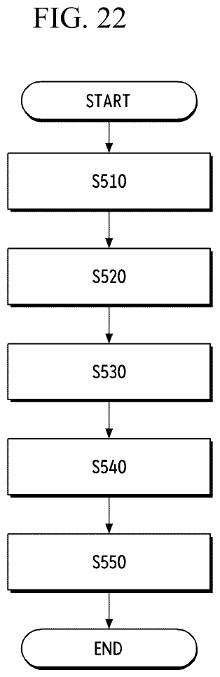

FIG. 22 is a flowchart detailing a determination process in the method of manufacturing the display device in the embodiment of the specification.

Referring to FIG. 22, the determination process in an embodiment may include an operation of detecting the position of the first area AR1 and the position of the second area AR2. In a display device on which the determination process in the embodiment is performed, an area (e.g., the second contact area CTA2) where the first area AR1 and the second area AR2 overlap in the third direction DR3 (e.g., the thickness direction) may be smaller than the second area AR2.

The operation of detecting the position of the first area AR1 and the position of the second area AR2 may be performed using a deep learning detection method that detects the type and position of an object (object detection). The deep learning detection method is an embodiment of artificial intelligence technology. The deep learning detection method is computer vision technology for accurately finding the type (class) and position (bounding box: x, y, width, length) of a meaningful object in an image or video. The deep learning detection method may be utilized to determine the positional relationship between the first area AR1 and the second area AR2. In an embodiment, the meaningful object may include the first area AR1 and the second area AR2, for example.

In the determination process, an operation of moving a plurality of cameras to a location where a laser drilling margin area LDA is disposed may be performed (refer to S510). The cameras may have coordinate values of the location, and the coordinate values may include correction coordinate values for shrinkage and/or expansion of a substrate due to a process performed in a pre-processing unit.

In a next operation, an operation of obtaining position information of the first area AR1 and the second area AR2 by utilizing the deep learning detection method may be performed (refer to S520).

In a next operation, an operation of defining a first center CR1 which is a center of the first area AR1, a second center CR2 which is a center of the second area AR2, and a first boundary BL1 and a second boundary BL2 may be performed. In addition, an operation of defining a plurality of points where the first boundary BL1 and the second boundary BL2 intersect may be performed (refer to S530).

In a next operation, an operation of defining an imaginary straight line IML that connects two of the points where the first boundary BL1 and the second boundary BL2 intersect may be performed (refer to S540).

In a next operation, an operation of determining the positional relationship between the first center CR1, the second center CR2, and the imaginary straight line IML may be performed (refer to S550).

In the case of a display device in which the second center CR2, the imaginary straight line IML and the first center CR1 are sequentially arranged, it may be determined that a recognition signal has been generated because a contact area (e.g., the second contact area CTA2) could not be appropriately secured. This display device may be determined to be a display device in which the contact area (e.g., the second contact area CTA2) between an auxiliary electrode and a common electrode cannot be appropriately secured.

In the case of a display device in which the imaginary straight line IML and the second center CR2 overlap in the thickness direction, it may be determined that the contact area (e.g., the second contact area CTA2) has been appropriately secured despite the generation of the recognition signal. This display device may be determined to be a display device in which the contact area (e.g., the second contact area CTA2) between the auxiliary electrode and the common electrode may be appropriately secured.

In the case of a display device in which the imaginary straight line IML, the second center CR2 and the first center CR1 are sequentially arranged, it may be determined that the contact area (e.g., the second contact area CTA2) has been appropriately secured despite the generation of the recognition signal. This display device may be determined to be a display device in which the contact area (e.g., the second contact area CTA2) between the auxiliary electrode and the common electrode may be appropriately secured.

The determination process in the embodiment may ultimately be a determination process on whether the contact area (e.g., the second contact area CTA2) has been appropriately secured. Therefore, the disclosure is not limited to the determination process according to the above-described embodiment. In an embodiment, an overlapping area between the first area AR1 and the second area AR2 may be simply calculated, for example. Then, when it is determined that the overlapping area is above or below a predetermined ratio, it may be determined whether the contact area (e.g., the second contact area CTA2) has been appropriately secured despite the generation of the recognition signal or whether the recognition signal has been generated because the contact area (e.g., the second contact area CTA2) could not be appropriately secured. The calculation of the overlapping area may be performed using technology (e.g., Open Source Computer Vision Library (“OpenCV”), Image Contour function, etc.) known to those skilled in the art.

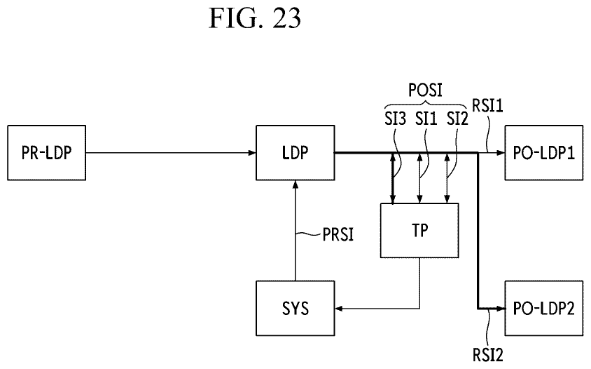

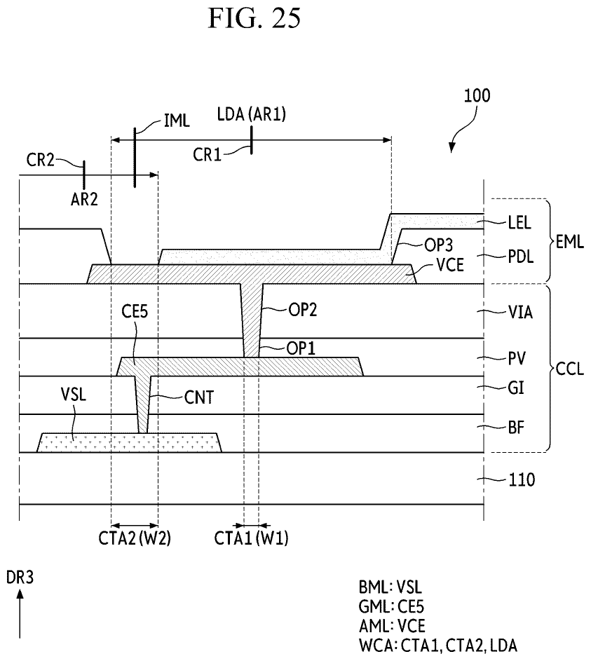

FIG. 23 is a block diagram illustrating a system in which a method of manufacturing a display device in an embodiment of the specification is implemented. FIG. 24 is a plan view of a display device in embodiments of the specification. FIG. 25 is a cross-sectional view corresponding to FIG. 24.

Referring to FIGS. 23, 24 and 25, in a display device to which a third post-signal SI3 is output and on which a second response path RSI2 is performed, an area (e.g., a second contact area CTA2) where a first area AR1 and a second area AR2 overlap in the third direction DR3 may be smaller than the second area AR2. A detection unit TP may transmit the third post-signal SI3 to the display device and perform the above-described determination process.

A first boundary BL1, a second boundary BL2, a first center CR1, and a second center CR2 may be defined in the first area AR1 and the second area AR2. The first boundary BL1 may include a plurality of points overlapping the second boundary BL2 in the third direction DR3. The points may include a first point P1 and a second point P2. An imaginary straight line IML connecting the first point P1 and the second point P2 may be defined based on the first point P1 and the second point P2. In an embodiment, the second center CR2, the imaginary straight line IML, and the first center CR1 may be sequentially arranged. The detection unit TP may output the third post-signal SI3, the second response path RSI2 may be performed, and an operation performed in a second post-processing unit PO-LDP2 may be performed on the display device. This display device may be a display device corresponding to a case where it is determined that a recognition signal has been generated because a contact area (e.g., the second contact area CTA2) could not be appropriately secured. A stopped process in a manufacturing process may be restarted.

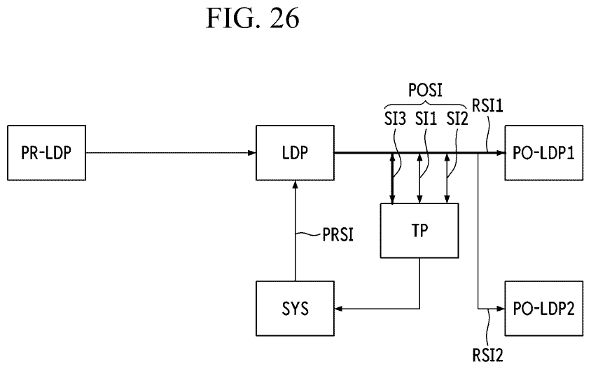

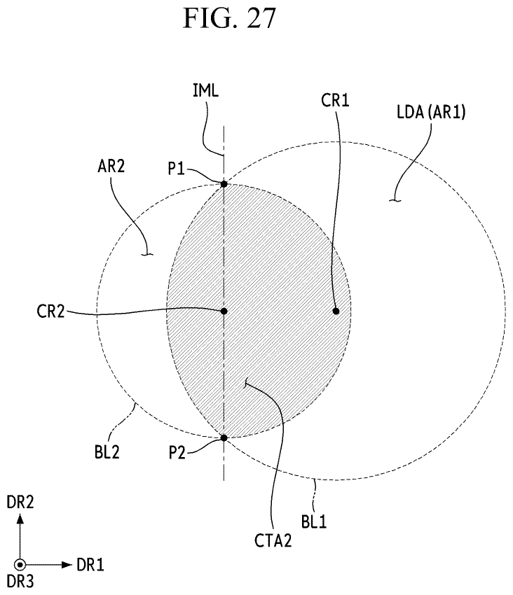

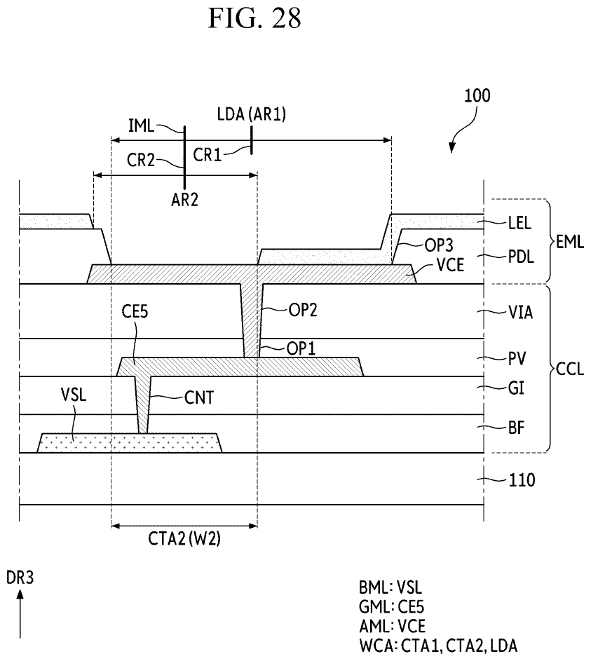

FIG. 26 is a block diagram illustrating a system in which a method of manufacturing a display device in an embodiment of the specification is implemented. FIG. 27 is a plan view of a display device in embodiments of the specification. FIG. 28 is a cross-sectional view corresponding to FIG. 27.

Referring to FIGS. 26, 27 and 28, in a display device to which a third post-signal SI3 is output and on which a first response path RSI1 is performed, an area (e.g., a second contact area CTA2) where a first area AR1 and a second area AR2 overlap in the third direction DR3 may be smaller than the second area AR2. A detection unit TP may transmit the third post-signal SI3 to the display device and perform the above-described determination process.

A first boundary BL1, a second boundary BL2, a first center CR1, and a second center CR2 may be defined in the first area AR1 and the second area AR2. The first boundary BL1 may include a plurality of points overlapping the second boundary BL2 in the third direction DR3. The points may include a first point P1 and a second point P2. An imaginary straight line IML connecting the first point P1 and the second point P2 may be defined based on the first point P1 and the second point P2. In an embodiment, the second center CR2 may overlap the imaginary straight line IML in the third direction DR3. The detection unit TP may output the third post-signal SI3, the first response path RSI1 may be performed, and an operation performed in a first post-processing unit PO-LDP1 may be performed on the display device. This display device may be a display device corresponding to a case where a contact area (e.g., the second contact area CTA2) is appropriately secured despite the generation of a recognition signal. A stopped process in a manufacturing process may be restarted.

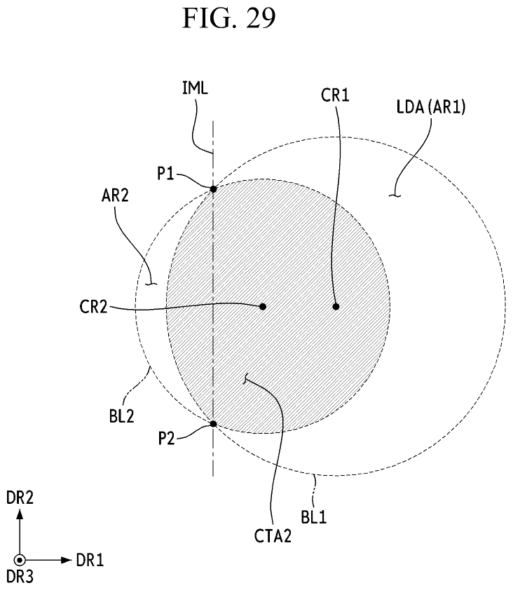

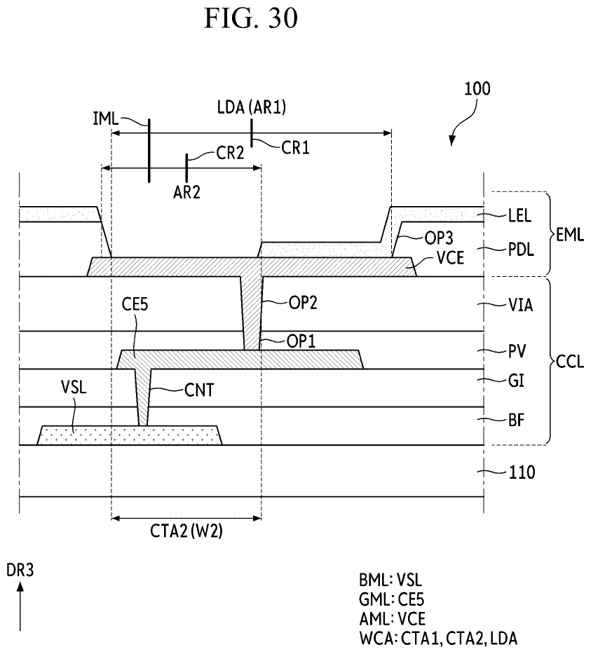

FIG. 29 is a plan view of a display device in embodiments of the specification. FIG. 30 is a cross-sectional view corresponding to FIG. 29.

Referring to FIGS. 29 and 30, in a display device to which a third post-signal SI3 is output and on which a first response path RSI1 is performed, an area (e.g., a second contact area CTA2) where a first area AR1 and a second area AR2 overlap in the third direction DR3 may be smaller than the second area AR2. A detection unit TP may transmit the third post-signal SI3 to the display device and perform the above-described determination process.

A first boundary BL1, a second boundary BL2, a first center CR1, and a second center CR2 may be defined in the first area AR1 and the second area AR2. The first boundary BL1 may include a plurality of points overlapping the second boundary BL2 in the third direction DR3. The points may include a first point P1 and a second point P2. An imaginary straight line IML connecting the first point P1 and the second point P2 may be defined based on the first point P1 and the second point P2. In an embodiment, the imaginary straight line IML, the second center CR2, and the first center CR1 may be sequentially arranged. The detection unit TP may output the third post-signal SI3, the first response path RSI1 may be performed, and an operation performed in a first post-processing unit PO-LDP1 may be performed on the display device. This display device may be a display device corresponding to a case where a contact area (e.g., the second contact area CTA2) is appropriately secured despite the generation of a recognition signal. A stopped process in a manufacturing process may be restarted.

In the above embodiments, the circular first area AR1 and the circular second area AR2 are defined in an embodiment, and the imaginary straight line IML is derived by assuming that the first area AR1 and the second area AR2 are circular or elliptical. However, the disclosure of the specification is not limited to this embodiment. The first response path RSI1 may be performed on a display device in which the area where the first area AR1 and the second area AR2 overlap in the third direction DR3 satisfies a predetermined criterion (speculation). An operation performed in a first post-processing unit PO-LDP1 will be performed on a display device that satisfies the predetermined criterion, and an operation performed in a second post-processing unit PO-LDP2 will be performed on a display device that does not satisfy the predetermined criterion. In an embodiment, only the display device on which the operation performed in the first post-processing unit PO-LDP1 has been performed will be finally produced, but the disclosure of the specification is not limited to this case.

In the specification, the concept of the imaginary straight line IML is provided as a predetermined method for determining whether to proceed to an operation performed in the first post-processing unit PO-LDP1 or an operation performed in the second post-processing unit PO-LDP2 when the first area AR1 and the second area AR2 overlap each other. In the specification, the concept of the imaginary straight line IML is provided as a method for determining whether a sufficient (or insufficient) contact area has been secured between an auxiliary electrode and a common electrode. However, the disclosure of the specification is not limited to the imaginary straight line IML, and any method for determining the area of an overlapping area may be included in the scope of the specification.

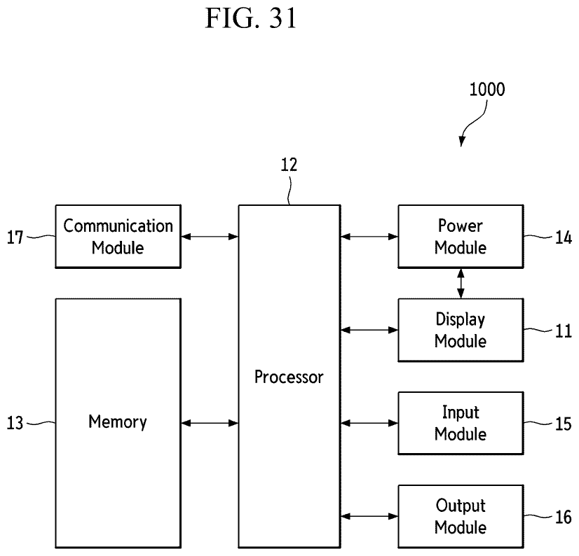

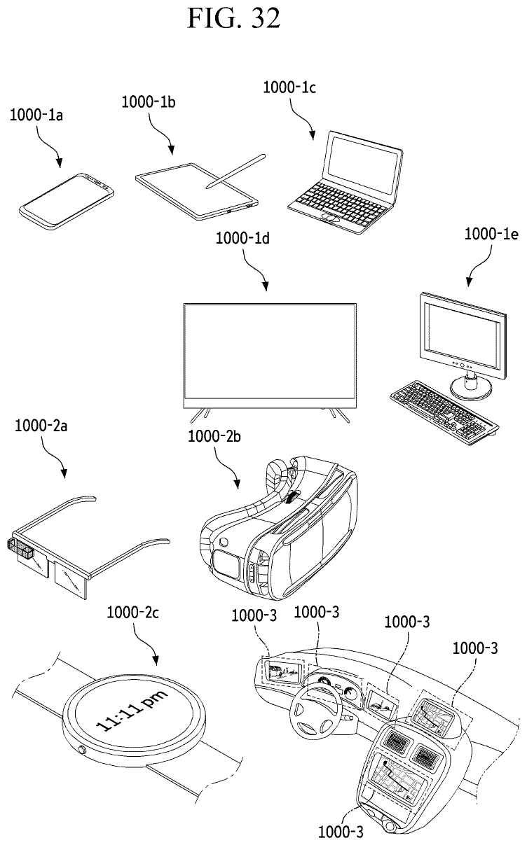

FIG. 31 is a block diagram of an electronic device in an embodiment of the specification. FIG. 32 is a schematic diagram of electronic devices according to various embodiments of the specification.

Referring to FIG. 31, an electronic device 1000 in an embodiment may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

The memory 13 may store data information desired for the operation of the processor 12 or the display module 11. When the processor 12 executes an application stored in the memory 13, an image data signal (also referred to as an image signal) and/or an input control signal may be transmitted to the display module 11, and the display module 11 may process the received signal and output image information through a display screen.

The power module 14 may include a power supply module such as a power adapter or a battery device. The power module 14 may include a power conversion module. The power conversion module may generate power desired for the operation of the electronic device 1000 by converting power supplied by the power supply module.

At least one of the elements of the electronic device 1000 described above may be included in a display device according to the above-described embodiments. In addition, some of individual modules functionally included in one module may be included in the display device, and other modules may be provided separately from the display device. In an embodiment, the display device may include the display module 11, and the processor 12, the memory 13 and the power module 14 may be provided not in the display device but in the form of other devices within the electronic device 1000, for example. In an embodiment, the electronic device 1000 may further include an input module 15, an output module 16 and a communication module 17.

Referring to FIG. 32, various electronic devices to which a display device in embodiments of the specification is applied may include image display electronic devices such as a smartphone 1000-1a, a tablet PC 1000-1b, a laptop 1000-1c, a television 1000-1d, and a desk monitor 1000-1e. In addition, the various electronic devices to which the display device in the embodiments of the specification is applied may include wearable electronic devices including a display module, such as smart glasses 1000-2a, a head-mounted display 1000-2b and a smart watch 1000-2c, and vehicle electronic devices 1000-3 including a display module, such as a center information display (“CID”) and a room mirror display placed on an instrument cluster, center fascia and dashboard of a vehicle.

Although embodiments of the disclosure have been described above with reference to the accompanying drawings, it will be understood by those having ordinary skill in the technical field to which the disclosure belongs that the disclosure may be practiced in other predetermined forms without altering the technical idea or essential features of the disclosure. It should therefore be understood that the embodiments described above are exemplary in all respects and are not intended to be limiting.

What is claimed is:

1. A display device comprising:
a substrate comprising:
a first area; and
a second area;
an anode conductive layer disposed on the substrate, the anode conductive layer comprising:
an auxiliary electrode;
a pixel defining layer covering an end of the auxiliary electrode and exposing at least a portion of an upper surface of the auxiliary electrode;
a light-emitting layer disposed on the anode conductive layer and exposing at least a portion of the upper surface of the auxiliary electrode; and
a common electrode disposed on the light-emitting layer and contacting the auxiliary electrode,
wherein the first area comprises an area exposed by the pixel defining layer on the upper surface of the auxiliary electrode, the second area comprises an area exposed by the light-emitting layer on the upper surface of the auxiliary electrode, and an area where the first area and the second area overlap in a thickness direction of the substrate is smaller than the second area.

2. The display device of claim 1, wherein the anode conductive layer further comprises a pixel electrode, and at least a portion of the light-emitting layer is disposed between the pixel electrode and the common electrode.

3. The display device of claim 1, wherein the substrate further comprises:
a display area comprising the first area and the second area; and
a non-display area surrounding the display area.

4. The display device of claim 1, wherein a first boundary is defined based on a boundary of the first area, a second boundary is defined based on a boundary of the second area, and the first boundary comprises a plurality of points overlapping the second boundary in the thickness direction.

5. The display device of claim 1, wherein a first boundary is defined based on a boundary of the first area, a second boundary is defined based on a boundary of the second area, and the first boundary comprises a first point and a second point overlapping the second boundary in the thickness direction.

6. The display device of claim 5, wherein a first center is defined from a center of the first area, a second center is defined from a center of the second area, and an imaginary straight line connecting the first point and the second point is defined.

7. The display device of claim 6, wherein the second center, the imaginary straight line, and the first center are sequentially arranged.

8. The display device of claim 6, wherein the second center overlaps the imaginary straight line in the thickness direction.

9. The display device of claim 6, wherein the imaginary straight line, the second center, and the first center are sequentially arranged.

10. The display device of claim 1, wherein the auxiliary electrode contacts the common electrode in the area where the first area and the second area overlap in the thickness direction of the substrate.

11. A method of manufacturing a display device, the method comprising:
forming a substrate which comprises a first area and a second area;
forming an anode conductive layer which is disposed on the substrate and comprises an auxiliary electrode;
forming a pixel defining layer which covers an end of the auxiliary electrode to expose at least a portion of an upper surface of the auxiliary electrode;
forming a light-emitting layer which is disposed on the anode conductive layer;
removing at least a portion of the light-emitting layer to expose at least a portion of the upper surface of the auxiliary electrode; and
detecting a position of the first area and a position of the second area,
wherein the first area comprises an area exposed by the pixel defining layer on the upper surface of the auxiliary electrode, the second area comprises an area exposed by the light-emitting layer on the upper surface of the auxiliary electrode, and an area where the first area and the second area overlap in a thickness direction of the substrate is smaller than the second area.

12. The method of claim 11, wherein the detecting the position of the first area and the position of the second area is performed using a deep learning detection method for detecting a type and position of an object.

13. The method of claim 11, further comprising comparing a positions of the first area and the second area.

14. The method of claim 13, wherein the comparing the positions of the first area and the second area comprises:
defining a first boundary based on a boundary of the first area;
defining a second boundary based on a boundary of the second area;
defining an imaginary straight line by connecting a plurality of points where the first boundary and the second boundary overlap in the thickness direction;
defining a first center from a center of the first area; and
defining a second center from a center of the second area.

15. The method of claim 14, wherein the comparing the positions of the first area and the second area further comprises comparing a positions of the imaginary straight line, the second center, and the first center.

16. An electronic device comprising:
a processor which provides an image signal;
a display module which receives the image signal from the processor and displays an image, the display module comprising:
a substrate comprising a first area and a second area;
an anode conductive layer disposed on the substrate and comprising an auxiliary electrode;
a pixel defining layer covering an end of the auxiliary electrode and exposing at least a portion of an upper surface of the auxiliary electrode;
a light-emitting layer disposed on the anode conductive layer and exposing at least a portion of the upper surface of the auxiliary electrode; and
a common electrode disposed on the light-emitting layer and contacting the auxiliary electrode; and
a power module which supplies power to the display module,
wherein the first area comprises an area exposed by the pixel defining layer on the upper surface of the auxiliary electrode, the second area comprises an area exposed by the light-emitting layer on the upper surface of the auxiliary electrode, and an area where the first area and the second area overlap in a thickness direction of the substrate is smaller than the second area.

17. The electronic device of claim 16, wherein the auxiliary electrode contacts the common electrode in the area where the first area and the second area overlap in the thickness direction of the substrate.

18. The electronic device of claim 16, wherein a first boundary is defined based on a boundary of the first area, a second boundary is defined based on a boundary of the second area, and the first boundary comprises a first point and a second point overlapping the second boundary in the thickness direction.

19. The electronic device of claim 18, wherein a first center is defined from a center of the first area, a second center is defined from a center of the second area, and an imaginary straight line connecting the first point and the second point is defined.

20. The electronic device of claim 19, wherein the imaginary straight line, the second center, and the first center are sequentially arranged.
